(19) United States
(12) Patent Application Publication
(10) Pub. No.: US 2026/0268975 A1
(43) Pub. Date: Sep. 10, 2026

(54) MEMORY DEVICE AND MEMORY SYSTEM

(71) Applicant: Kioxia Corporation, Tokyo (JP)

(72) Inventors: Mitsuaki HONMA, Fujisawa Kanagawa (JP); Ren ASHIBE, Hiratsuka Kanagawa (JP)

(73) Assignee: Kioxia Corporation, Tokyo (JP)

(21) Appl. No.: 19/309,666

(22) Filed: Aug. 26, 2025

(30) Foreign Application Priority Data
Mar. 5, 2025 (JP) 2025-034880

(51) Int. Cl. G11C 16/08; G11C 16/14; G11C 16/30

(52) U.S. Cl. CPC G11C 16/08; G11C 16/14; G11C 16/30

(57) ABSTRACT

According to one embodiment, a memory devise includes: a first memory cell array including first and second memory cells each coupled to first and second word lines respectively, and configured to memorize first and second data respectively; a register; and a sequencer, wherein the first and the second data each includes first and second bits respectively, the sequencer executes a first process including: applying a plurality of different voltages to the first word line to read the first bit from the first memory cell repeatedly; specifying a first voltage based on results of readings the first bit; and storing a first parameter that specifies the first voltage in the register, and executes a second process including: obtaining the first parameter from the register; estimating a second voltage based on the first parameter; and reading the second bit from the second memory cell using the second voltage.

### CROSS-REFERENCE TO RELATED APPLICATIONS

This application is based upon and claims the benefit of priority from Japanese Patent Application No. 2025-034880, filed Mar. 5, 2025, the entire contents of which are incorporated herein by reference.

### FIELD

Embodiments described herein relate generally to a memory device and a memory system.

### BACKGROUND

A NAND flash memory is known as a memory device capable of storing data in a non-volatile manner.

### BRIEF DESCRIPTION OF THE DRAWINGS

FIG. 1 is a block diagram illustrating an example of the configuration of an information processing system according to an embodiment.

FIG. 2 is a block diagram illustrating an example of the configuration of a non-volatile memory according to the embodiment.

FIG. 3 is a circuit diagram illustrating an example of the circuit configuration of a memory cell array according to the embodiment.

FIG. 4 is a cross-sectional view illustrating an example of the structure of the memory cell array according to the embodiment.

FIG. 5 is a diagram illustrating an example of threshold voltage distributions of a plurality of memory cell transistors included in the memory cell array according to the embodiment, as well as examples of data stored therein.

FIG. 6 is a block diagram illustrating an example of the configuration of a sense amplifier module according to the embodiment.

FIG. 7 is a circuit diagram illustrating an example of the configuration of a sense circuit according to the embodiment.

FIG. 8 is a diagram for illustrating an example of a tracking read performed in a non-volatile memory according to the embodiment.

FIG. 9 is a diagram for illustrating an example of a tracking read performed in the non-volatile memory according to the embodiment.

FIG. 10 is a waveform diagram illustrating an example of a lower page tracking read performed in the non-volatile memory according to the embodiment.

FIG. 11 is a flowchart illustrating an example of a shift read process executed in the non-volatile memory according to the embodiment.

FIG. 12 is a diagram illustrating an example of a method for estimating a shift amount in a first shift read executed in the non-volatile memory according to the embodiment.

FIG. 13 is a sequence diagram illustrating an example of a process which the non-volatile memory and memory controller according to the embodiment perform when a first shift read and a tracking read corresponding to the first shift read are executed.

FIG. 14 is a command sequence diagram illustrating an example of the first shift read performed in the memory system according to the embodiment.

FIG. 15 is a sequence diagram illustrating an example of a process which the non-volatile memory and memory controller according to the embodiment perform when a tracking read corresponding to a second shift read is executed.

FIG. 16 is a sequence diagram illustrating an example of a process which the non-volatile memory and memory controller according to the embodiment perform when the second shift read is executed.

FIG. 17 is a command sequence diagram illustrating an example of the tracking read, which corresponds to the second shift read and is performed in the memory system according to the embodiment.

FIG. 18 is a command sequence diagram illustrating an example of the second shift read performed in the memory system according to the embodiment.

FIG. 19 is a sequence diagram illustrating an example of a read process flow for each plane, performed in the memory system according to the embodiment when a second shift read is applied in an asynchronous independent plane read.

FIG. 20 is a command sequence diagram illustrating an example of how the tracking read corresponding to the second shift read is performed in a memory system according to a first modification of the embodiment.

### DETAILED DESCRIPTION

In general, according to one embodiment, a memory device includes: a first memory cell array including a first memory cell coupled to a first word line and configured to memorize first data, and a second memory cell coupled to a second word line and configured to memorize second data; a register; and a sequencer, wherein the first data includes a first bit, the second data includes a second bit, upon receipt of a first command, the sequencer executes a first process including: applying a plurality of different voltages within a first range to the first word line to read the first bit from the first memory cell a plurality of times; specifying a first voltage within the first range based on results of reading the first bit a plurality of times; and storing a first parameter that specifies the first voltage in the register, and upon receipt of a second command, the sequencer executes a second process including: obtaining the first parameter from the register; estimating a second voltage based on the first parameter; and reading the second bit from the second memory cell using the second voltage.

Embodiments will now be described below with reference to the accompanying drawings. The drawings are schematic, and the dimensions and scales in the drawings do not necessarily correspond to those of actual products. In the description below, components having the same functions and configurations will be denoted by the same reference symbols. Where elements having similar configurations are to be specifically distinguished from each other, different letters or numerals may be appended to the same reference numeral.

In the description below, in a case where a first element is described as being “coupled” to a second element, this includes not only the case where the first element is indirectly coupled to the second element via an intermediate element that is conductive either at all times or at selected times, but also the case where the first element is directly coupled to the second element without an intermediate element.

### 1. Configuration

### 1.1 Information Processing System

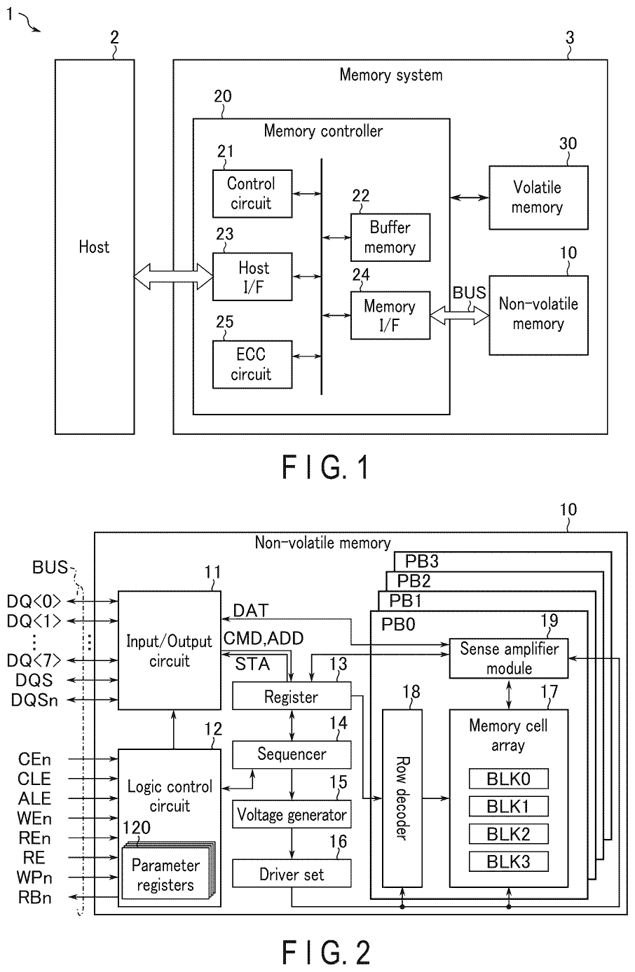

An information processing system according to the first embodiment will be described. FIG. 1 is a block diagram illustrating an example of the configuration of the information processing system according to the embodiment. As shown in FIG. 1, the information processing system 1 includes a host 2 and a memory system 3.

The host 2 is a data processing device that processes data using the memory system 3. The host 2 is, for example, a personal computer or a server in a data center.

The memory system 3 is a storage device configured to be coupled to the host 2. The memory system 3 is, for example, a memory card such as an SD™ card, a universal flash storage (UFS), or a solid-state drive (SSD). The memory system 3 performs data write, read, and erase operations in response to a request from the host 2. The memory system 3 may execute data write, read, and erase operations as an internal process. The internal process is a process that is executed within the memory system 3 without reference to a request from the host 2.

### 1.2 Memory System

The internal configuration of the memory system 3 according to the embodiment will be described with continued reference to FIG. 1.

The memory system 3 includes a non-volatile memory 10, a memory controller 20, and a volatile memory 30. The non-volatile memory 10, the memory controller 20, and the volatile memory 30 may be combined to form a single semiconductor device.

The non-volatile memory 10 is, for example, a NAND flash memory capable of storing data in a non-volatile manner. The non-volatile memory 10 can also be referred to as a memory device.

The memory controller 20 is, for example, an integrated circuit such as an SoC (System on a Chip). The functions of each portion of the memory controller 20 can be realized by dedicated hardware, a processor that executes a program and firmware, or a combination of these. The memory controller 20 controls the non-volatile memory 10, based on a request from the host 2. Specifically, the memory controller 20 writes data requested to be written to the non-volatile memory 10, based on a write command issued by the host 2. The memory controller 20 also reads data requested to be read from the non-volatile memory 10, based on a read command issued by the host 2, and outputs it to the host 2. The memory controller 20 erases data requested to be erased from the non-volatile memory 10, based on an erase command issued by the host 2.

The volatile memory 30 is, for example, a DRAM (Dynamic Random Access Memory). The volatile memory 30 stores firmware for managing the non-volatile memory 10 and various management information. The volatile memory 30 stores, for example, a predetermined read voltage (default value) used in a read process executed in the non-volatile memory 10. The predetermined read voltage may also be stored in the non-volatile memory 10.

### 1.3 Memory Controller

With continued reference to FIG. 1, the internal configuration of the memory controller 20 according to the embodiment will be described.

The memory controller 20 includes a control circuit 21, a buffer memory 22, a host interface circuit (host I/F) 23, a memory interface circuit (memory I/F) 24, and an ECC (Error Checking and Correcting) circuit 25, which are coupled to each other via an internal bus. The undermentioned functions of the memory controller 20 can be realized by either a hardware configuration or a combined configuration of hardware resources and firmware.

The control circuit 21 is a circuit that controls the overall operation of the memory controller 20. The control circuit 21 includes, for example, a processor such as a CPU (Central Processing Unit), and a volatile memory such as an SRAM (Static Random Access Memory) or DRAM that is used as a working area of the processor. For example, the control circuit 21 commands the non-volatile memory 10 to perform a write operation, a read operation, and an erase operation, based on a request issued by the host 2.

The buffer memory 22 is, for example, a semiconductor memory such as an SRAM or a DRAM. The buffer memory 22 temporarily stores write data received from the host 2 and read data received by the memory controller 20 from the non-volatile memory 10. The buffer memory 22 may be provided outside the memory controller 20.

The host interface circuit 23 is coupled to the host 2 via a host bus. The host bus is, for example, a bus complaint with the PCIe (PCI EXPREESS™ (Peripheral Component Interconnect EXPRESS)), UFS (Universal Flash Storage), SD™ interface, SAS (Serial Attached SCSI (Small Computer System Interface)), SATA (Serial ATA (Advanced Technology Attachment)), or NVMe (NVM EXPRESS™ (Non-Volatile Memory EXPRESS)). The host interface circuit 23 manages communication between the host 2 and the memory controller 20. The host interface circuit 23 transfers, for example, commands and data received from the host 2 to the control circuit 21 or the buffer memory 22.

The memory interface circuit 24 is coupled to the non-volatile memory 10 via a bus BUS. The bus BUS is, for example, a bus compliant with the SDR (Single Data Rate) interface, toggle DDR (Double Data Rate) interface, or ONFI (Open NAND Flash Interface). The memory interface circuit 24 manages communication between the memory controller 20 and the non-volatile memory 10. The memory interface circuit 24 transmits commands, address information, and write data to the non-volatile memory 10 in response to instructions from the control circuit 21. The memory interface circuit 24 also receives read data from the non-volatile memory 10.

The ECC circuit 25 performs error detection and correction processing for data stored in the non-volatile memory 10. More specifically, when data is written, the ECC circuit 25 generates an error correction code, such as parity, and appends it to the write data. The error correction code is, for example, a hard-decision decoding code such as a BCH (Bose-Chaudhuri-Hocquenghem) code or an RS (Reed-Solomon) code, or a soft-decision decoding code such as an LDPC (Low-Density Parity-Check) code. When data is read, the ECC circuit 25 performs a decoding process of the error correction code to detect the presence or absence of an error. If an error is detected, the ECC circuit 25 identifies the bit position where the error is detected and correct the error. The ECC circuit 25 has an error correctable bit number, which is the upper limit of the number of errors that can be corrected.

### 1.4 Non-volatile Memory

Next, the internal configuration of the non-volatile memory according to the first embodiment will be described. FIG. 2 is a block diagram illustrating an example of the configuration of the non-volatile memory according to the embodiment.

The non-volatile memory 10 includes a plurality of planes PB, an input/output circuit 11, a logic control circuit 12, a register 13, a sequencer 14, a voltage generator 15, and a driver set 16. In the example shown in FIG. 2, the non-volatile memory 10 includes four planes PB0, PB1, PB2, and PB3.

The plurality of planes PB0 to PB3are units of divided memory areas. The planes PB0 to PB3 can operate independently of each other. In other words, the non-volatile memory 10 includes a plurality of memory areas that can be controlled independently of each other. Each of the plurality of planes PB0 to PB3 includes a memory cell array 17, a row decoder 18, and a sense amplifier module 19.

The input/output circuit 11 and the logic control circuit 12 are interface circuits that transmit and receive various signals to and from the memory controller 20 via the bus BUS. Signals transmitted and received by the input/output circuit 11 include, for example, signals DQ<0>, DQ<1>, . . . , and DQ<7> (collectively referred to as a signal DQ<7:0>), as well as DQS and DQSn. The signals transmitted and received by the logic control circuit 12 include, for example, signals CEn, CLE, ALE, WEn, RE, REn, WPn, and RBn. In this specification, the suffix “n” at the end of a signal name indicates the inverted logic of the signal without the “n.” Specifically, in the case of a signal without the suffix “n,” it means that the signal is asserted when the signal is at the “H (High)” level. In the case of a signal with the suffix “n,” it means that the signal is asserted when the signal is at the “L (Low)” level.

The signal DQ<7:0> is, for example, an 8-bit signal. The signal DQ<7:0> constitutes the actual data transmitted and received between the non-volatile memory 10 and the memory controller 20. The signal DQ<7:0> includes, for example, data DAT, a command CMD, address information ADD, and status information STA. The data DAT includes read data and write data.

The signals DQS and DQSn are data strobe signals. These signals DQS and DQSn notify the non-volatile memory 10 and the memory controller 20 of the input/output timing of the signal DQ<7:0>.

The signal CEn is a chip enable signal. The signal CEn enables the non-volatile memory 10.

The signals CLE and ALE are a command latch enable signal and an address latch enable signal, respectively. The signals CLE and ALE notify the non-volatile memory 10 that the signals DQ<7:0> input from the memory controller 20 represent a command CMD and address information ADD, respectively.

The signal WEn is a write enable signal. The signal WEn instructs the non-volatile memory 10 to write the input signals DQ<7:0>.

The signals RE and REn are read enable signals. The signals RE and REn instruct the non-volatile memory 10 to output the signal DQ<7:0>.

The signal WPn is a write protect signal. The signal WPn instructs the non-volatile memory 10 to prohibit write and erase operations.

The signal RBn is a ready/busy signal. The signal RBn indicates whether the non-volatile memory 10 is in a ready state (a state in which it can accept commands from the memory controller 20) or a busy state (a state in which it cannot accept commands from the memory controller 20). The signal RBn is “H” level when the non-volatile memory 10 is in the ready state, and is “L” level when the non-volatile memory 10 is in the busy state.

The input/output circuit 11 transmits the address information ADD, command CMD, and write data DAT contained in the signal DQ<7:0>, which is input from the memory controller 20, to the register 13 and the sense amplifier module 19 of the corresponding plane PB. The input/output circuit 11 outputs the status information STA and read data DAT received from the register 13 and the sense amplifier module 19 of the corresponding plane PB to the memory controller 20.

The logic control circuit 12 receives various control signals input from the memory controller 20. The logic control circuit 12 controls each of the input/output circuit 11 and the sequencer 14, based on the control signals. For example, the logic control circuit 12 notifies the input/output circuit 11 that the signal DQ<7:0> received by the input/output circuit 11 is a command CMD, address information ADD, or the like. The logic control circuit 12 instructs the input/output circuit 11 to input or output the signal DQ<7:0>. The logic control circuit 12 controls the sequencer 14 to enable the non-volatile memory 10. The logic control circuit 12 also outputs the signal RBn to the memory controller 20 to notify the memory controller 20 whether the non-volatile memory 10 is in a ready state or a busy state.

The logic control circuit 12 includes a plurality of parameter registers 120. The number of the plurality of parameter registers 120 corresponds, for example, to the number of planes PB provided in the non-volatile memory 10, and each parameter register 120 corresponds to a respective plane PB. Each parameter register 120 stores a shift amount obtained by a tracking read. A tracking read and a shift amount will be described later. The parameter register 120 may further store other parameters related to the read process.

The register 13 temporarily stores the command CMD, the address information ADD, and the status information STA. The command CMD includes, for example, instructions for causing the sequencer 14 to execute a read operation, a write operation, an erase operation, etc. The address information ADD includes, for example, a block address, a page address, and a column address. For example, the block address, the page address, and the column address are used to select a block BLK, a word line, and a bit line, respectively. The status information STA is updated under the control of the sequencer 14, and is transferred to the input/output circuit 11.

The sequencer 14 controls the overall operation of the non-volatile memory 10. For example, based on the command CMD stored in the register 13, the sequencer 14 controls the voltage generator 15, and the row decoder 18 and sense amplifier module 19 in the selected plane PB, and executes a read operation, a write operation, an erase operation, etc. In addition, the sequencer 14 receives a result of the threshold voltage tracking from the sense amplifier module 19 in the selected plane PB, transfers it to the logic control circuit 12, and stores it in the parameter register 120 corresponding to the selected plane PB. In the read process, the sequencer 14 obtains the result of the threshold voltage tracking stored in the corresponding parameter register 120, and can vary the magnitude of the voltage generated by the voltage generator 15 accordingly.

The sequencer 14 can independently control the operations of the plurality of planes PB0 to PB3. For example, the sequencer 14 is capable of reading data in parallel from both planes PB0 and PB1. When the sequencer 14 reads data in parallel from the planes PB0 and PB1, the read process from the plane PB0 and the read process from the plane PB1 can be executed synchronously or asynchronously.

The voltage generator 15 generates voltages used in a write operation, a read operation, an erase operation, etc.

The driver set 16 supplies the voltages generated by the voltage generator 15 to the memory cell array 17, row decoder 18, and sense amplifier module 19 in the selected plane PB.

The memory cell array 17 includes a plurality of blocks BLK, a plurality of bit lines, and a plurality of word lines. A block BLK is a collection of memory cell transistors capable of storing data in a non-volatile manner. In the example shown in FIG. 2, the memory cell array 17 included in the plane PB0 includes four blocks BLK0 to BLK3. Although not shown, the memory cell arrays 17 included in the planes PB1 to PB3 each include four blocks BLK0 to BLK3. The block BLK is used, for example, as an erase unit of data DAT in an erase operation. Each memory cell transistor is associated with a pair of a bit line and a word line.

The row decoder 18 selects a corresponding one block BLK in the memory cell array 17 in the same plane PB, for example, based on a block address stored in the register 13. The row decoder 18 further selects a word line in the selected block BLK, for example, based on a page address stored in the register 13. The row decoder 18 applies a voltage generated by the voltage generator 15 to the selected word line in the selected block BLK.

The sense amplifier module 19 includes a sense amplifier capable of determining data, based on the voltage of an associated bit line, a latch circuit that temporarily holds data, etc. The sense amplifier module 19 selects a bit line, based on the column address stored in the register 13. In a write operation, the sense amplifier module 19 applies a desired voltage to each bit line in accordance with the write data DAT received from the input/output circuit 11. In a read operation, the sense amplifier module 19 determines the data stored in the memory cell transistor, based on the magnitude of the voltage on the selected bit line. Then, the sense amplifier module 19 transfers the determination result to the input/output circuit 11 as read data DAT.

### 1.5 Memory Cell Array

Next, the configuration of the memory cell array according to the embodiment will be described. 1.5.1 Circuit Configuration

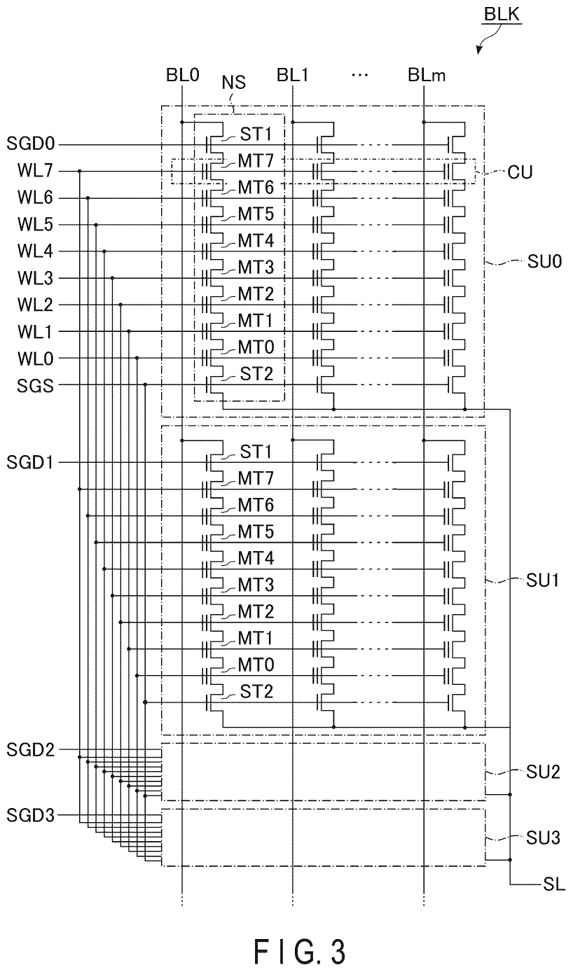

FIG. 3 is a circuit diagram illustrating an example of the configuration of the memory cell array according to the embodiment. FIG. 3 shows one block BLK, which is one of a plurality of blocks BLK included in the memory cell array 17. As shown in FIG. 3, the block BLK includes, for example, four string units SU0 to SU3. It should be noted that the number of string units SU is arbitrary.

Each string unit SU includes a plurality of NAND strings NS respectively associated with bit lines BL0 to BLm (m is an integer equal to or greater than 1). Each NAND string NS includes, for example, eight memory cell transistors MT0 to MT7 and select transistors ST1 and ST2. Each memory cell transistor MT includes a control gate and a charge storage film, and stores data in a non-volatile manner, based on the amount of charge in the charge storage film. Each of the select transistors ST1 and ST2 is used for selecting the string unit SU during various operations.

In each NAND string NS, the memory cell transistors MT0 to MT7 are coupled in series in this order. The drain of the select transistor ST1 is coupled to the associated bit line BL, and the source of the select transistor ST1 is coupled to the drain of the memory cell transistor MT7. The drain of the select transistor ST2 is coupled to the source of the memory cell transistor MT0, and the source of the select transistor ST2 is coupled to a source line SL.

The control gates of the memory cell transistors MT0 to MT7 in the same block BLK are coupled to word lines WL0 to WL7, respectively. The gates of the select transistors ST1 in the string units SU0 to SU3 are coupled to select gate lines SGD0 to SGD3, respectively. The gates of the select transistors ST2 are coupled to a select gate line SGS.

Different column addresses are assigned to the bit lines BL0 to BLm. Each bit line BL is shared by NAND strings NS to which the same column address is assigned in each block BLK. Each of the word lines WL0 to WL7 is provided in each block BLK. The source line SL is shared, for example, by the plurality of blocks BLK.

A set of memory cell transistors MT coupled to a common word line WL in one string unit SU are referred to as a cell unit CU, for example. For example, the storage capacity of the cell unit CU including memory cell transistors MT each storing 1-bit data is defined as “1 page data.” The cell unit CU may have a storage capacity of two page data or more in accordance with the number of bits of data stored in the memory cell transistor MT.

In the description below, reference will be made to a case where one memory cell transistor MT can store three bits of data. The write mode in which three bits of data are stored in the memory cell transistor MT is referred to as a TLC (Triple Level Cell) mode. The three bits of data written in the TLC mode and stored in the memory cell transistor are respectively called a lower bit, a middle bit, and an upper bit, in order from the least significant bit. The set of lower bits, the set of middle bits, and the set of upper bits stored in the plurality of memory cell transistors MT included in the same cell unit CU are respectively called a “lower page,” a “middle page,” and an “upper page.”

The circuit configuration of the memory cell array 17 provided in the non-volatile memory 10 according to the present embodiment is not limited to the above description. For example, the number of string units SU included in each block BLK may be designed to be an arbitrary number. The number of memory cell transistors MT included in each NAND string NS and the number of select transistors ST1 and ST2 may be designed to be arbitrary numbers. 1.5.2 Memory Structure

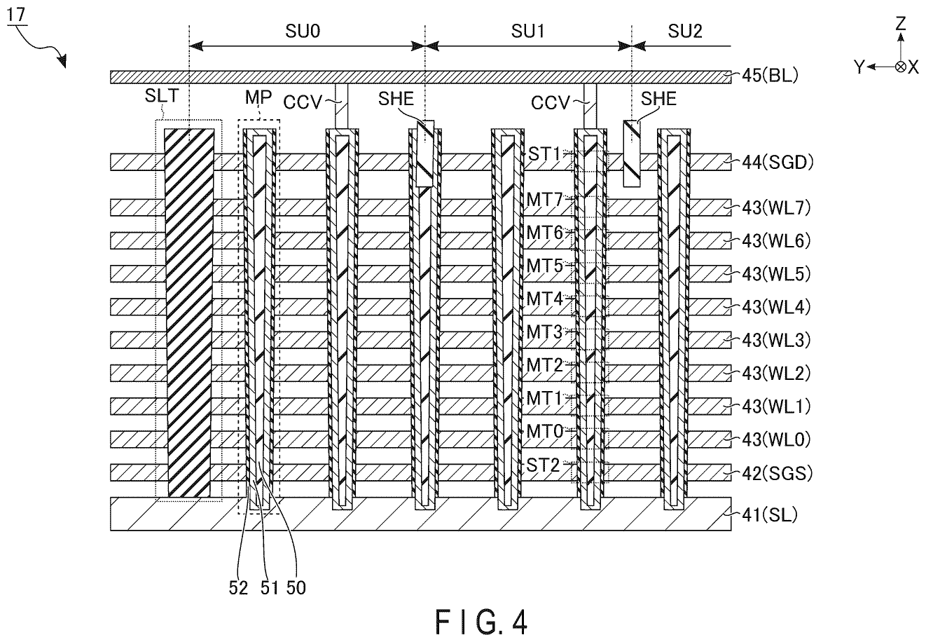

FIG. 4 is a cross-sectional view illustrating an example of the structure of the memory cell array according to the embodiment. The memory cell array 17 according to the embodiment has a stacked interconnect structure in which the source line SL, select gate lines SGS and SGD, and word lines WL0 to WL7 are stacked with spacing between them. In FIG. 4, the X direction is the direction in which the word lines WL extend. The Y direction is the direction in which the bit lines BL extend. The Z direction is the direction in which the stacked interconnect structures are arranged.

As shown in FIG. 4, the memory cell array 17 has a structure in which an interconnect layer 41, an interconnect layer 42, a plurality of interconnect layers 43, an interconnect layer 44, and an interconnect layer 45 are stacked in this order with spacing from each other. The interconnect layer 41 corresponds to the source line SL and includes, for example, polysilicon. The interconnect layer 42 corresponds to the select gate line SGS and includes, for example, tungsten (W) or molybdenum (Mo). The plurality of interconnect layers 43 correspond to the word lines WL0 to WL7, respectively, and include, for example, tungsten or molybdenum. The interconnect layer 44 corresponds to the select gate line SGD, and includes, for example, tungsten or molybdenum. The interconnect layer 45 corresponds to the bit line BL, and includes, for example, copper (Cu). Although not shown, an insulator including, for example, silicon oxide (SiO) is embedded between the interconnect layers 41 to 45, and the interconnect layers 41 to 45 are electrically insulated from each other.

The memory cell array 17 includes a plurality of memory pillars MP, a plurality of insulating members SLT and SHE, and a plurality of contacts CCV.

Each memory pillar MP extends through the interconnect layer 42, the plurality of interconnect layers 43, and the interconnect layer 44 in the Z direction, and has a bottom face that is in contact with the interconnect layer 41. The portion where the memory pillar MP and the interconnect layer 42 intersect each other functions as the select transistor ST2. The portions where the memory pillar MP and the plurality of interconnect layers 43 intersect each other function as the memory cell transistors MT0 to MT7. The portion where the memory pillar MP and the interconnect layer 44 intersect each other functions as the select transistor ST1.

Each memory pillar MP includes a core film 50, a semiconductor film 51, and a stacked film 52. The core film 50 extends in the Z direction. The core film 50 includes an insulator such as silicon oxide. The semiconductor film 51 covers the periphery of the core film 50. The semiconductor film 51 is used as a channel (current path) of the memory cell transistors MT0 to MT7 and the select transistors ST1 and ST2. At the lower end of the memory pillar MP, part of the semiconductor film 51 is in contact with the interconnect layer 41. The semiconductor film 51 includes, for example, silicon. The stacked film 52 covers the side face of the semiconductor film 51, except for the portion where the semiconductor film 51 is in contact with the interconnect layer 41. The stacked film 52 includes, for example, a gate insulating film, a charge storage film, a block insulating film, etc. With this configuration, each memory pillar MP can function as one NAND string NS.

The insulating member SLT is formed in a plate shape extending in the X direction and the Z direction, and divides the interconnect layer 42, the plurality of interconnect layers 43, and the interconnect layer 44 in the Y direction. Each region divided by the insulating member SLT corresponds to one block BLK. The insulating member SLT includes, for example, silicon oxide.

The plurality of insulating members SHE are formed in a plate shape extending in the X direction and the Z direction, and divide the interconnect layer 44 in the Y direction. The regions divided by the plurality of insulating members SLT and SHE correspond to the select gate lines SGD0 to SGD3, respectively. The insulating members SHE include, for example, silicon oxide.

The plurality of contacts CCV are columnar contacts extending in the Z direction. Each contact CCV is in contact with the semiconductor film 51 of the corresponding memory pillar MP at its bottom face, and is in contact with the corresponding interconnect layer 45 at its top face, and thus electrically couples the two.

### 1.5.3 Threshold Voltage Distributions

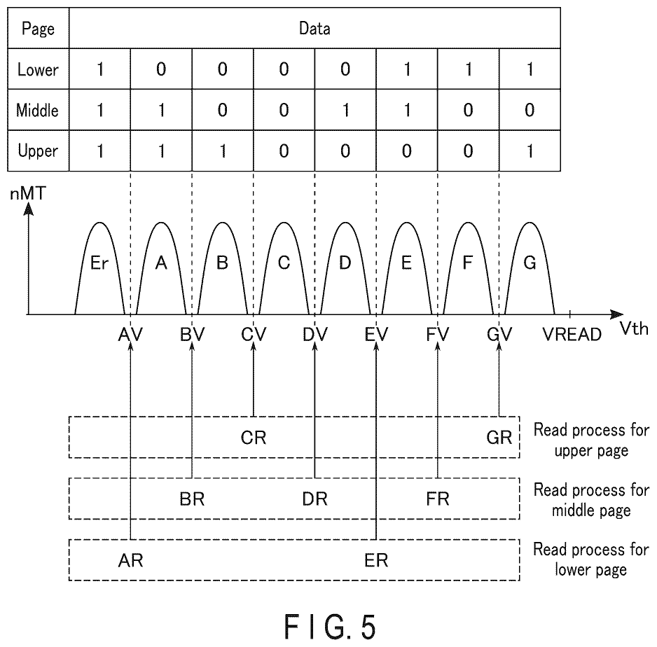

FIG. 5 is a diagram illustrating an example of threshold voltage distributions of a plurality of memory cell transistors included in the memory cell array according to the embodiment, as well as examples of data stored therein. In FIG. 5, the horizontal axis represents the threshold voltage (Vth), and the vertical axis represents the number of memory cell transistors (nMT) having that threshold voltage. In a case where a memory cell transistor MT stores three bits of data, its threshold voltage distribution can be roughly divided into eight types. In the description below, these eight types of threshold voltage distributions (write levels) are expressed, in order from the lowest threshold voltage, as the “Er” level, the “A” level, the “B” level, the “C” level, the “D” level, the “E” level, the “F” level, and the “G” level.

In a case where the memory cell transistor MT is in an erased state, the threshold voltage of the memory cell transistor MT is included in the “Er” level. In a case where data is written to the memory cell transistor MT, the threshold voltage of the memory cell transistor MT is included in one of the “Er” to “G” levels. Different 3 bits of data are assigned to each of the threshold voltage distributions from the “Er” level to the “G” level. Preferably, the data assignments for any two adjacent levels are configured such that only one bit differs between them. An example of the data assignment to the threshold voltage distributions is listed below.
“Er” level: “111 (upper bit/middle bit/lower bit)” data
“A” level: “110” data
“B” level: “100” data
“C” level: “000” data
“D” level: “010” data
“E” level: “011” data
“F” level: “001” data
“G” level: “101” data

Voltages AV, BV, CV, DV, EV, FV, and GV shown in FIG. 5 are voltages used to distinguish between two adjacent states during the read process. Voltage VREAD is a voltage applied to a non-selected word line during a read process. When the voltage VREAD is applied to the gate, the memory cell transistor MT is turned on regardless of the data stored therein. The relationships between these voltage values are AV<BV<CV<DV<EV<FV<GV<VREAD.

Each threshold distribution is defined by the read voltage used in the read operation. Specifically, the threshold voltage included in the “Er” level is lower than the read voltage AV. The threshold voltage included in the “A” level is equal to or higher than the read voltage AV and is lower than the read voltage BV. The threshold voltage included in the “B” level is equal to or higher than the read voltage BV and is lower than the read voltage CV. The threshold voltage included in the “C” level is equal to or higher than the read voltage CV and is lower than the read voltage DV. The threshold voltage included in the “D” level is equal to or higher than the read voltage DV and is lower than the read voltage EV. The threshold voltage included in the “E” level is equal to or higher than the read voltage EV and is lower than the read voltage FV. The threshold voltage included in the “F” level is equal to or higher than the read voltage FV and is lower than the read voltage GV. The threshold voltage included in the “G” level is equal to or higher than the read voltage GV and is lower than the voltage VREAD.

The read process for the lower page includes read processes AR and ER. The read process AR uses a read voltage AV that distinguishes between the “Er” level and the “A” level. The read process ER uses a read voltage EV that distinguishes between the “D” level and the “E” level.

The read process for the middle page includes read processes BR, DR, and FR. The read process BR uses a read voltage BV that distinguishes between the “A” level and the “B” level. The read process DR uses a read voltage DV that distinguishes between the “C” level and the “D” level. The read process FR uses a read voltage FV that distinguishes between the “E” level and the “F” level.

The read process for the upper page includes read processes CR and GR. The read process CR uses a read voltage CV that distinguishes between the “B” level and the “C” level. The read process GR uses a read voltage GV that distinguishes between the “F” level and the “G” level.

### 1.6 Sense Amplifier Module

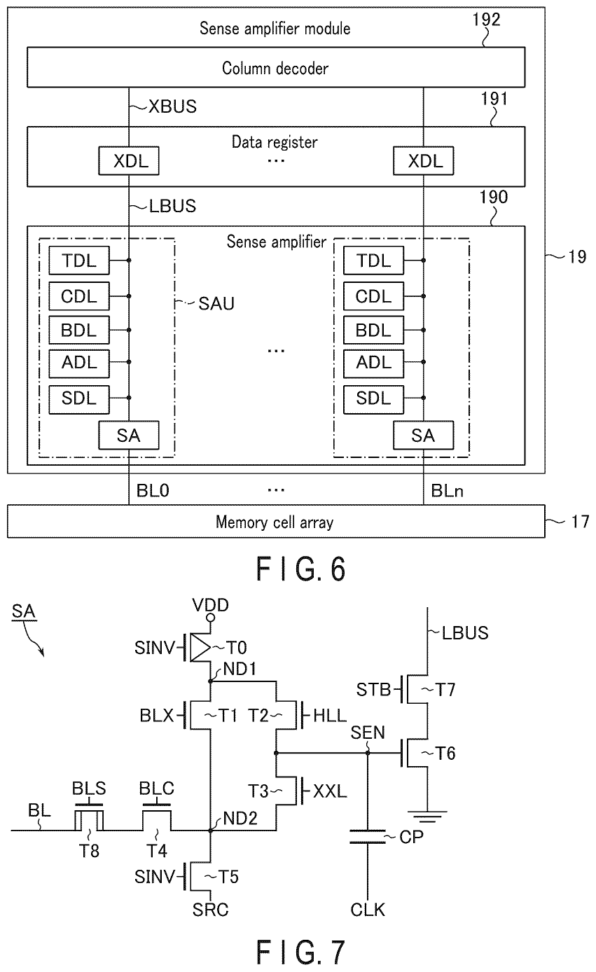

Next, a description will be given of the configuration of the sense amplifier module according to the embodiment. FIG. 6 is a block diagram illustrating an example of the configuration of the sense amplifier module according to the embodiment. As shown in FIG. 6, the sense amplifier module 19 includes a sense amplifier 190, a data register 191, and a column decoder 192.

The sense amplifier 190 includes a plurality of sense amplifier units SAU provided for each bit line BL. The data register 191 includes a plurality of latch circuits XDL provided for each sense amplifier unit SAU.

Each sense amplifier unit SAU includes, for example, a sense circuit SA and five latch circuits SDL, ADL, BDL, CDL, and TDL. The sense circuit SA and the latch circuits SDL, ADL, BDL, CDL, and TDL are commonly coupled to the corresponding latch circuit XDL via a bus LBUS. In other words, the latch circuit XDL, the sense circuit SA, and the latch circuits SDL, ADL, BDL, CDL, and TDL are coupled such that they can transmit and receive data via the bus LBUS. Each sense amplifier unit SAU may include any number of latch circuits; it may include six or more latch circuits, for example.

During a read process, the sense circuit SA senses the threshold voltage of the memory cell transistor MT via the corresponding bit line BL and determines whether the data stored in the memory cell transistor MT is “0” or “1.” During a write process, the sense circuit SA applies a voltage to the corresponding bit line BL, based on write data.

The latch circuits SDL, ADL, BDL, CDL, and TDL temporarily store either data DAT read from the memory cell array 17 or data DAT to be written to the memory cell transistor MT. For example, in the case of a read operation, the read data DAT is stored in one of the latch circuits SDL, ADL, BDL, CDL, and TDL. For example, in the case of a write operation, data DAT transmitted from the latch circuit XDL and to be written to the memory cell transistor MT is stored in one of the latch circuits SDL, ADL, BDL, CDL, and TDL.

Each latch circuit XDL is used as a cache memory between the sense amplifier unit SAU and the column decoder 192. More specifically, data DAT received from the column decoder 192 and to be written to the memory cell transistor MT is transmitted, via the latch circuit XDL, to either the latch circuits SDL, ADL, BDL, CDL, and TDL, or to the sense circuit SA. Data DAT read from the memory cell transistor MT stored in the latch circuits SDL, ADL, BDL, CDL, and TDL or the sense circuit SA is transmitted to the column decoder 192 via the latch circuit XDL.

The column decoder 192 is coupled to the corresponding latch circuits XDL via a plurality of buses XBUS. During a write operation, the column decoder 192 receives data DAT to be written to the memory cell transistor MT from the input/output circuit 11. The column decoder 192 then transmits the data DAT to the latch circuit XDL corresponding to the column address. During a read operation, the column decoder 192 receives data DAT read from the latch circuit XDL corresponding to the column address. The column decoder 192 then transmits the data DAT to the input/output circuit 11.

### 1.7 Sense Circuit

Next, the configuration of the sense circuit according to the embodiment will be described. FIG. 7 is a circuit diagram illustrating an example of the configuration of the sense circuit according to the embodiment. As shown in FIG. 7, the sense circuit SA includes nine transistors T0 to T8 and a capacitor CP. The transistor T0 is a P-type MOS transistor. The transistors T1 to T8 are N-type MOS transistors. The transistor T8 is an N-type MOS transistor with a higher withstand voltage than the transistors T1 to T7, and has a withstand voltage high enough to transfer the write voltage applied to the word line WL to be written in the write operation. In the description below, in a case where the drain and source of a transistor are not distinguished, the terminals will be referred to as a first end and a second end, respectively.

A power supply voltage VDD is supplied to the first end of the transistor T0. The second end of the transistor T0 is coupled to a node ND1. The gate of the transistor T0 is coupled to a node SINV.

The first end of the transistor T1 is coupled to the node ND1. The second end of the transistor T1 is coupled to a node ND2. The gate of the transistor T1 is coupled to a node BLX.

The first end of the transistor T2 is coupled to the node ND1. The second end of the transistor T2 is coupled to a node SEN. The gate of the transistor T2 is coupled to a node HLL.

The first end of the transistor T3 is coupled to the node SEN. The second end of the transistor T3 is coupled to the node ND2. The gate of the transistor T3 is coupled to a node XXL.

The first end of the transistor T4 is coupled to the node ND2. The second end of the transistor T4 is coupled to the first end of the transistor T8. The second end of the transistor T8 is coupled to the bit line BL corresponding to the sense circuit SA. The gate of the transistor T4 is coupled to a node BLC. The gate of the transistor T8 is coupled to a node BLS.

The first end of the transistor T5 is coupled to the node ND2. The second end of the transistor T5 is coupled to a node SRC. The gate of the transistor T5 is coupled to the node SINV.

The first end of the transistor T6 is grounded. The second end of the transistor T6 is coupled to the first end of the transistor T7. The second end of the transistor T7 is coupled to the bus LBUS. The gate of the transistor T6 is coupled to the node SEN. The gate of the transistor T7 is coupled to a node STB.

The first end of the capacitor CP is coupled to the node SEN. A clock signal CLK is supplied to the second end of the capacitor CP.

With the above configuration, during a read operation, the sense circuit SA can determine the data DAT stored in the memory cell transistor MT, based on the voltage of the node SEN. As a result of the determination, the data DAT read to the node SEN is transferred to the latch circuit SDL etc. via the bus LBUS.

### 2. Read Operation

Next, the read operation of the memory system 3 according to the embodiment will be described.

The non-volatile memory 10 can perform three types of read operations: normal read, tracking read, and shift read. In a read operation of the memory system 3, one or more of these read types may be selected to read data.

The normal read is a normal read process in which data is read using a preset read voltage. The tracking read is a read process for determining an optimal read voltage. The shift read is a read process in which data is read using a voltage shifted from the preset read voltage. The tracking read and the shift read will be described below.

### 2.1 Tracking Read

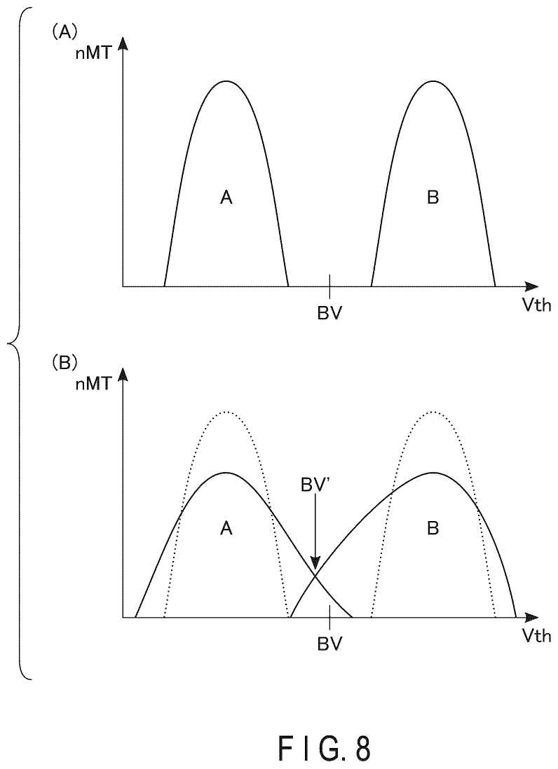

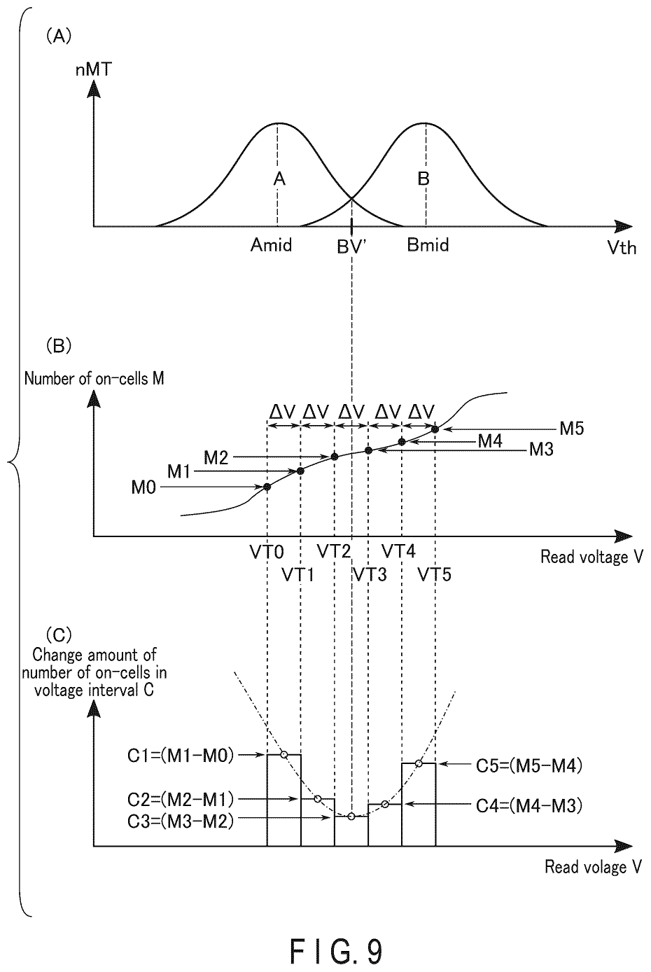

The tracking read will be described in detail below with reference to FIG. 8 and FIG. 9. FIG. 8 and FIG. 9 are diagrams for illustrating an example of a tracking read performed in the non-volatile memory according to the embodiment. In FIG. 8, the overlap between the threshold voltage distributions of the “A” level and the “B” level is shown, with these two levels presented as a representative example. In FIG. 9, a tracking read corresponding to the read process BR for the threshold voltage distribution of the “B” level is shown as a representative example.

The threshold voltage distributions of the memory cell transistors MT included in one cell unit CU are independent of each other just after writing, as shown in part (A) of FIG. 8. However, the threshold voltage of the memory cell transistor MT may vary due to program disturbance and data retention after writing, as well as due to read disturbance after reading. As a result, the distribution width of the threshold voltage distribution may widen or the distribution may move, so that adjacent threshold voltage distributions may overlap each other, as shown in part (B) of FIG. 8. In this case, if a read is performed using the initially set read voltage BV, the number of error bits (i.e., bits in which erroneous data is read) may increase. If the number of error bits exceeds the error correction capability of the ECC circuit 25, not all data can be accurately corrected, resulting in a reduction in memory reliability.

In a case where the threshold voltage distributions overlap, it is desirable to reduce the number of error bits by shifting the read voltage to a new value (such as BV′ in part (B) of FIG. 8) that corresponds to the point where the overlap between the two levels is smaller, and by performing the read operation using the new read voltage. As the new value that corresponds to the point where the overlap between the two levels is smaller, the voltage at a minimum point of the threshold voltage distribution is frequently used. The voltage at the minimum point of the threshold voltage distribution is referred to as the minimum point voltage.

The memory system 3 searches for a minimum point voltage between the threshold voltage distributions of two adjacent levels by performing a tracking read, and calculates a shift amount from the preset read voltage. FIG. 9 illustrates the concept of searching for the minimum point voltage by performing a tracking read. For example, consider a case where the threshold voltage distributions of the “A” level and the “B” level overlap, as shown in part (A) of FIG. 9. Part (B) of FIG. 9 shows the relationship between the read voltage V and the number M of memory cell transistors MT that are turned on in response to the read voltage (i.e., the number of on-cells). Part (C) of FIG. 9 shows the change amounts C of the number of on-cells M between two different voltages (i.e., the change amounts of the numbers of on-cells in the voltage intervals).

As shown in part (B) of FIG. 9, when the read voltage V is gradually increased, the number M of on-cells increases rapidly at a voltage slightly higher than voltage Amid, which is the mode of the “A” level, and dM/dV becomes maximum. The mode mentioned here is a voltage at which the distribution probability of the threshold voltage is highest in a certain level of the threshold voltage distribution. When the read voltage V is further increased, the rate of increase of the number M of on-cells decreases, and the rate of increase of the number M of on-cells becomes minimum at a certain value of the read voltage V. In a case where the threshold voltage distributions of the “A” and “B” levels do not overlap, the minimum rate of increase in the number M of on-cells is zero. In the example shown in FIG. 9, however, the two distributions overlap, so the minimum rate of increase in the number M of on-cells is a positive value greater than zero. If the read voltage V is further increased, the rate of increase of the number M of on-cells increases again, and dM/dV becomes maximum at a voltage slightly lower than voltage Bmid, which is the mode of the “B” level.

The minimum point voltage can be estimated based on the change in the number M of on-cells relative to the change in voltage V in the selected cell unit CU. Specifically, a read is first performed using voltage VT0 as the read voltage. The resulting number of on-cells is M0. Next, a read is performed using voltage VT1, which is ΔV higher than voltage VT0, as the read voltage. The resulting number of on-cells is M1. Thus, the number of memory cell transistors MT that are newly turned on while the read voltage rises from voltage VT0 to voltage VT1 is C1=M1−M0, as shown in part (C) of FIG. 9. In other words, the number of cells that have a threshold voltage between voltage VT0 and voltage VT1 is C1.

Next, a read is performed using voltage VT2, which is ΔV higher than voltage VT1, as the read voltage. The resulting number of on-cells is M2. Thus, the number of memory cell transistors MT that are newly turned on while the read voltage rises from voltage VT1 to voltage VT2 is C2=M2−M1. In other words, the number of cells that have a threshold voltage between voltage VT1 and voltage VT2 is C2. In the example shown in FIG. 9, C2 is smaller than C1, as shown in part (C) of FIG. 9. It is therefore considered that the voltage at which dM/dV reaches its minimum is higher than voltage VT1.

Next, a read is performed using voltage VT3, which is ΔV higher than voltage VT2, as the read voltage. The resulting number of on-cells is M3. Thus, the number of memory cell transistors MT that are newly turned on while the read voltage rises from voltage VT2 to voltage VT3 is C3=M3−M2. In other words, the number of cells that have a threshold voltage between voltage VT2 and voltage VT3 is C3. In the example shown in FIG. 9, C3 is smaller than C2, as shown in part (C) of FIG. 9. It is therefore considered that the voltage at which dM/dV reaches its minimum is higher than voltage VT2.

Next, a read is performed using voltage VT4, which is ΔV higher than voltage VT3, as the read voltage. The resulting number of on-cells is M4. Thus, the number of memory cell transistors MT that are newly turned on while the read voltage rises from voltage VT3 to voltage VT4 is C4=M4−M3. In other words, the number of cells that have a threshold voltage between voltage VT3 and voltage VT4 is C4. In the example shown in FIG. 9, C4 is larger than C3, as shown in part (C) of FIG. 9. It is therefore considered that the voltage at which dM/dV reaches its minimum is lower than voltage VT3.

Next, a read is performed using voltage VT5, which is ΔV higher than voltage VT4, as the read voltage. The resulting number of on-cells is M5. Thus, the number of memory cell transistors MT that are newly turned on while the read voltage rises from voltage VT4 to voltage VT5 is C5=M5−M4. In other words, the number of cells that have a threshold voltage between voltage VT4 and voltage VT5 is C5. In the example shown in FIG. 9, C5 is larger than C4, as shown in part (C) of FIG. 9. It is therefore considered that the voltage at which dM/dV reaches its minimum is lower than voltage VT4.

As a result of the above, a threshold voltage distribution function as shown by the dash-dot line in part (C) of FIG. 9 can be estimated by the numbers C of cells in the voltage intervals. As shown in part (C) of FIG. 9, the threshold voltage distribution function is estimated to have a minimum point between voltage VT2 and voltage VT3, which is a voltage interval where the number C of cells is minimum. The estimated minimum point is the point where the overlap of the threshold voltage distributions of the “A” and “B” levels is estimated to be the smallest. By executing the read process BR that uses the voltage at the minimum point of the threshold voltage distribution function as the read voltage, the number of bits resulting in read errors can be reduced. The minimum point voltage estimated as above is referred to as a shift voltage BV′.

Then, the shift amount of the shift voltage BV′ from the preset read voltage BV is calculated. For instance, in the example shown in FIG. 8 and FIG. 9, the shift amount ΔBV corresponding to the read voltage BV can be calculated as (BV′−BV). The tracking read for calculating the shift amount ΔBV in this manner is referred to as a tracking read for the read voltage BV. Similarly, a tracking read is executed for each of read voltages AV, CV, DV, EV, FV, and GV, and shift amounts ΔAV, ΔCV, ΔDV, ΔEV, ΔFV, and ΔGV are calculated.

As can be seen from this, the tracking read is a process that involves: calculating the number of memory cell transistors MT that are turned on using a plurality of voltages; estimating a voltage at which the threshold voltage distribution function reaches its minimum; and calculating a shift amount from a preset read voltage. The calculated shift amount is sent to the logic control circuit 12 and stored in the corresponding parameter register 120.

The tracking read is executed on a per-page basis. Specifically, when a tracking read for a lower page is instructed, tracking reads for the read voltages AV and EV are executed sequentially. When a tracking read for a middle page is instructed, tracking reads for the read voltages BV, DV, and FV are executed sequentially. When a tracking read for an upper page is instructed, tracking reads for the read voltages CV and GV are executed sequentially.

Thereafter, a shift read is executed using the calculated shift voltage. This shift read executed by the same command as the tracking read is referred to as a calibrated read. The calibrated read enables reading of data with a small number of bits that may result in read errors. The non-volatile memory 10 outputs the data DAT read by the calibration read to the memory controller 20. The calibrated read can be omitted, if so desired.

In the example shown above, the tracking read was executed using six voltages VT0, VT1, VT2, VT3, VT4, and VT5, but the number of voltages used in the tracking read is not limited to this, and the tracking read may be executed using more voltages or fewer voltages. The number of voltages used in the tracking read depends on the magnitude of ΔV. In general, the smaller the ΔV, the higher the accuracy in estimating the voltage at the minimum point of the threshold voltage distribution function; however, the read time required for the tracking read increases.

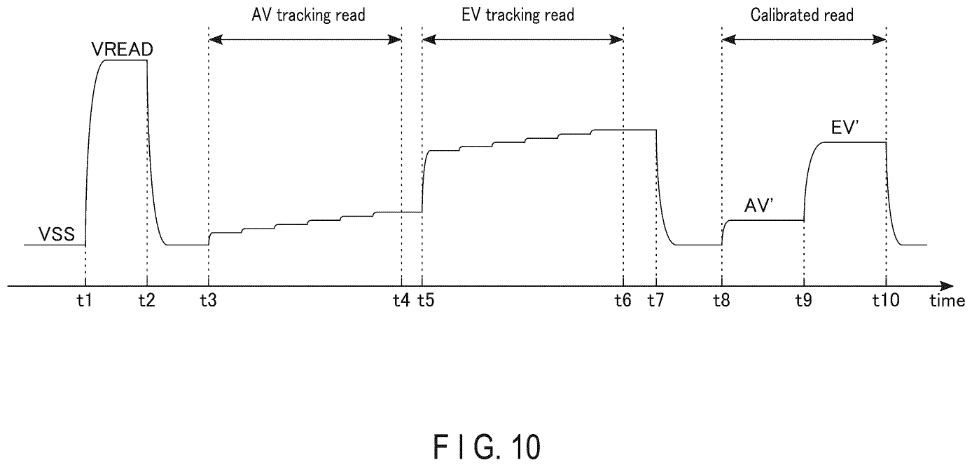

FIG. 10 is a waveform diagram illustrating an example of a lower page tracking read performed in the non-volatile memory according to the embodiment. FIG. 10 shows the waveform of a voltage applied to the word line WL of a read target in the lower page tracking read.

As shown in FIG. 10, at the start of the tracking read, the word line WL that is to be the target of the tracking read (hereinafter referred to as a selected word line WL) is applied with a voltage VSS. The voltage VSS is, for example, a ground voltage.

First, at time t1, a voltage VREAD is applied to the selected word line WL. This removes residual electrons from the channel of the memory cell transistor MT included in the cell unit CU corresponding to the selected word line WL. Thereafter, at time t2, the voltage VSS is applied to the selected word line WL.

Next, from time t3, a tracking read is executed for a read voltage AV. In the tracking read for the read voltage AV, the voltage applied to the selected word line WL is started from a voltage lower than AV, then incrementally increased by ΔV, and the number of on-cells is counted at each voltage. This allows the minimum point of the threshold voltage distribution function to be estimated, and enables calculation of a shift voltage AV′ and shift amount ΔAV. The calculated shift amount ΔAV is transmitted to and stored in the parameter register 120. At time t4, the tracking read for the read voltage AV ends.

Next, from time t5, a tracking read for a read voltage EV is started. In the tracking read for the read voltage EV, a process similar to that of the tracking read for the read voltage AV is performed to calculate a shift voltage EV′ and a shift amount ΔEV. The calculated shift amount ΔEV is transmitted to the parameter register 120 and stored therein. When the tracking read for the read voltage EV ends at time t6, the voltage VSS is applied to the selected word line WL at time t7.

Next, a calibrated read is executed from time t8. At time t8, the shift voltage AV′ is applied to the selected word line WL and a read process AR is executed. Thereafter at time t9, the shift voltage EV′ is applied to the selected word line WL and a read process ER is executed. Thus, the data of the lower page stored in the cell unit CU coupled to the selected word line WL is read. When the calibrated read ends, the voltage VSS is applied to the selected word line WL at time t10.

In this manner, a tracking read for the lower page is executed. Although not shown, tracking reads are executed for the middle and upper pages in a similar manner.

### 2.2 Shift Read

A shift read is a read process using a voltage (shift voltage) shifted from an initially set read voltage. For example, a shift read is performed using, as the shift voltage, a voltage corresponding to the minimum point of the threshold voltage distribution function estimated by the tracking read.

### 2.2.1 Overview

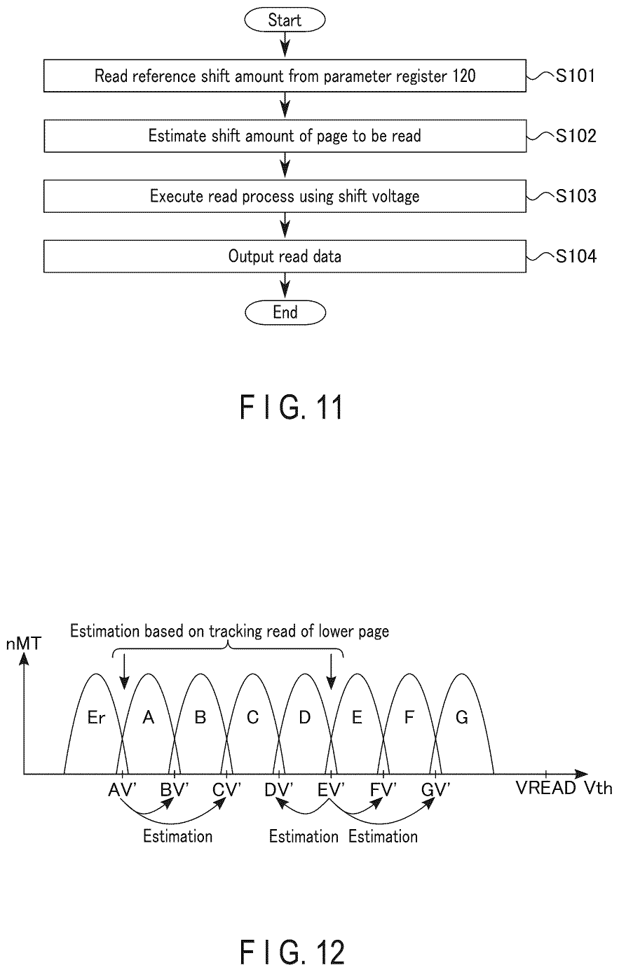

FIG. 11 is a flowchart illustrating an example of a shift read process executed in the non-volatile memory according to the embodiment. The flow of the shift read will be described with reference to FIG. 11.

Upon instruction from the memory controller 20, the non-volatile memory 10 starts a shift read. First, the non-volatile memory 10 reads the corresponding reference shift amount from the parameter register 120 (S101). The reference shift amount read at this time is a value that was previously calculated through tracking read and stored in the parameter register 120.

Thereafter, the non-volatile memory 10 estimates a shift amount used for calculating a shift voltage of the page to be read, based on the value of the reference shift amount (S102). At this time, shift amounts (ΔAV to ΔGV) are estimated for the read voltages AV to GV, respectively. The method for estimating the shift amounts will be described later.

Thereafter, the non-volatile memory 10 executes a read process on the cell unit CU to be read, using a shift voltage obtained by adding a shift amount to a preset read voltage (S103). Specifically, in reading the lower page data, a read process AR is executed using a shift voltage AV′ (AV′=AV+ΔAV), and then a read process ER is executed using a shift voltage EV′ (EV′=EV+ΔEV). In reading the middle page data, a read process BR is executed using a shift voltage BV′ (BV′=BV+ΔBV), then a read process DR is executed using a shift voltage DV′ (DV′=DV+ΔDV), and then a read process FR is executed using a shift voltage FV′ (FV′=FV+ΔFV). In reading the upper page data, a read process CR is executed using a shift voltage CV′ (CV′=CV+ΔCV), and then a read process GR is executed using a shift voltage GV′ (GV′=GV+ΔGV).

Thereafter, the non-volatile memory 10 outputs the read page data to the memory controller 20 (S104). When the data output is completed, the shift read is terminated (end).

In the memory system 3 according to the embodiment, a shift amount for the page to be read by the shift read can be estimated using the result of a tracking read performed on a different page within the selected cell unit CU. This serves as a shift amount estimation method used for the shift read. The shift read using this shift amount estimation method will be referred to as a first shift read. In addition, a shift amount for the cell unit CU coupled to the word line WL and string unit SU to be read by the shift read can be estimated using the result of a tracking read performed on a different cell unit CU. The shift read using this shift amount estimation method will be referred to as a second shift read. The processes of the first shift read and second shift read will be described below.

### 2.2.2 First Shift Read

In the first shift read, a tracking read is performed using the read voltage corresponding to the read process of one of the lower page, middle page, and upper page stored in the selected cell unit CU. From the result of this tracking read, shift amounts corresponding to the other two pages are estimated, and a shift read is performed using shift voltages calculated based on the shift amounts. In the description below, reference will be made to a case where a tracking read is performed on the read voltage corresponding to the read process of the lower page, and shift amounts corresponding to the middle page and upper page are estimated from the result of this tracking read.

### 2.2.2.1 Shift Amount Estimation

FIG. 12 is a diagram illustrating an example of a method for estimating a shift amount in the first shift read executed in the non-volatile memory according to the embodiment. In the example shown in FIG. 12, tracking reads for the read voltages AV and EV corresponding to the lower page are performed in the selected cell unit CU to estimate shift voltages AV′ and EV′, and shift amounts ΔAV and ΔEV are calculated. Then, shift amounts ΔBV, ΔCV, ΔDV, ΔFV, and ΔGV of the read voltages BV, DV, and FV corresponding to the middle page and the read voltages CV and GV corresponding to the upper page are estimated using the shift amounts ΔAV and ΔEV. For example, the shift amounts ΔBV and ΔCV of the read voltages BV and CV are estimated from the shift amount ΔAV of the read voltage AV. The shift amounts ΔDV, ΔFV and ΔGV of the read voltages DV, FV, and GV are estimated from the shift amount ΔEV of the read voltage EV. Then, shift voltages shifted by the estimated shift amounts are calculated, and the middle and upper pages are read using the shift voltages.

In the selected cell unit CU, the shift amount Y of each read voltage for the middle and upper pages is associated with the shift amount X of each read voltage for the lower page, for example, by the following Equation (1):

$$Y = aX + b + e \qquad ( 1 )$$

It should be noted that the shift amount X is the difference between the initially set read voltage and the voltage at the minimum point of the threshold voltage distribution function, and includes ΔAV (=AV′−AV) and ΔEV (=EV′−EV). The shift amount Y is the difference between the initially set read voltage and the voltage at the minimum point of the threshold voltage distribution function, and includes ΔBV (=BV′−BV), ΔCV (=CV′−CV), ΔDV (=DV′−DV), ΔFV (=FV′−FV), and ΔGV (=GV′−GV). The coefficients “a” and “b” are preset values for calculating the shift amount Y, based on the shift amount X. The coefficients “a” and “b” are determined, for example, according to the characteristics of the memory cells. The coefficient “e” represents an error term.

As can be seen from the above, there is a correlation between the shift amount X and the shift amount Y, so that the shift amounts of the middle and upper pages can be estimated by detecting the shift amount of the lower page. The correlation between shift amounts X and Y can be stronger when the levels are closer to each other. For this reason, in the present embodiment, the shift amounts ΔBV and ΔCV are estimated from the shift amount ΔAV, and the shift amounts ΔDV, ΔFV, and ΔGV are estimated from the shift amount ΔEV. It should be noted that the estimation method is not limited to the above; for example, the shift amounts ΔDV, ΔFV, and ΔGV may be estimated from the shift amount ΔAV, or the shift amounts ΔBV and ΔCV may be estimated from the shift amount ΔEV. In addition, the shift amounts of the lower page and the upper page may be estimated from the shift amounts of the middle page, or the shift amounts of the lower page and the middle page may be estimated from the shift amounts of the upper page.

Equation (1) describes a case where the shift amounts X and Y are associated by a linear function, but the association is not limited thereto. For example, the shift amounts X and Y may be associated by an arbitrary polynomial function.

### 2.2.2.2 Flow of First Shift Read

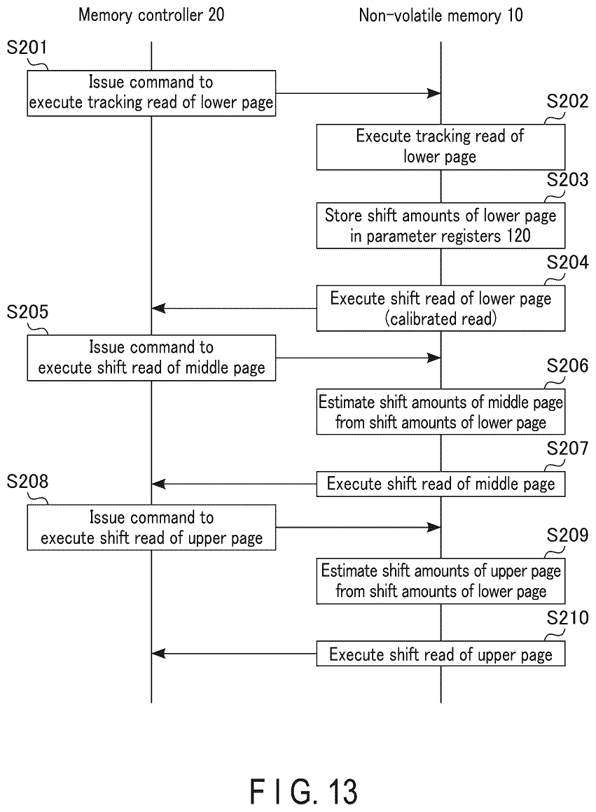

FIG. 13 is a sequence diagram illustrating an example of a process which the non-volatile memory and memory controller according to the embodiment perform when a first shift read and a tracking read corresponding to the first shift read are executed. The flow of the first shift read will be described with reference to FIG. 13.

First, the memory controller 20 issues a command to the non-volatile memory 10 to execute a tracking read of the lower page of the selected cell unit CU (S201). Upon receipt of the tracking read command of the lower page, the non-volatile memory 10 executes a tracking read of the lower page of the cell unit CU (S202). As a result of the tracking read, shift voltages AV′ and EV′ that are minimum points of the threshold voltage distribution function, and shift amounts ΔAV and ΔEV are calculated. Then, the non-volatile memory 10 stores the shift amounts ΔAV and ΔEV obtained as a result of the tracking read in the corresponding parameter registers 120 in the logic control circuit 12 (S203).

Next, the non-volatile memory 10 executes a calibrated read that includes read processes AR and ER using the shift voltages AV′ and EV′ obtained as a result of the tracking read (S204). After the read process AR, the sense circuit SA transfers the data read in the read process AR to the latch circuit ADL. The sense circuit SA also transfers the data read in the read process AR to the latch circuit XDL. After the read process ER, the sense circuit SA transfers the data read in the read process ER to the latch circuit BDL. Then, the sense circuit SA transmits inverted data of the data read in the read process ER to the latch circuit XDL and performs an EXOR operation. As a result, the lower page data is stored in the latch circuit XDL. The non-volatile memory 10 outputs the lower page data stored in the latch circuit XDL to the memory controller 20.

Next, the memory controller 20 issues a command to the non-volatile memory 10 to execute a first shift read of the middle page of the selected cell unit CU (S205). Upon receipt of the first shift read command of the middle page, the non-volatile memory 10 refers to the shift amounts ΔAV and ΔEV stored in the corresponding parameter registers 120 and estimates shift amounts ΔBV, ΔDV, and ΔFV, using, for example, Equation (1) (S206).

Then, the non-volatile memory 10 calculates shift voltages BV′, DV′, and FV′ from the estimated shift amounts ΔBV, ΔDV, and ΔFV, and sequentially executes read processes BR, DR, and FR, using the calculated shift voltages (S207). After the read process BR, the sense circuit SA transfers the data read in the read process BR to the latch circuit ADL. The sense circuit SA also transfers the data read in the read process BR to the latch circuit XDL. After the read process DR, the sense circuit SA transfers the data read in the read process DR to the latch circuit BDL. Then, the sense circuit SA transmits inverted data of the data read in the read process DR to the latch circuit XDL and performs an EXOR operation. After the read process FR, the sense circuit SA transfers the data read in the read process FR to the latch circuit CDL. Then, the sense circuit SA transmits the read data in the read process FR to the latch circuit XDL and performs an EXOR operation. As a result, the middle page data is stored in the latch circuit XDL. The non-volatile memory 10 outputs the middle page data to the memory controller 20. The shift amounts ΔBV, ΔDV, and ΔFV obtained at this time may be transmitted to the corresponding parameter registers 120 in the logic control circuit 12 and stored therein.

Next, the memory controller 20 issues a command to the non-volatile memory 10 to execute a first shift read of the upper page of the selected cell unit CU (S208). Upon receipt of the first shift read command of the upper page, the non-volatile memory 10 refers to the shift amounts ΔAV and ΔEV stored in the corresponding parameter registers 120 and estimates shift amounts ΔCV and ΔGV using, for example, Equation (1) (S209).

Then, the non-volatile memory 10 calculates shift voltages CV′ and GV′ from the estimated shift amounts ΔCV and ΔGV, and sequentially executes read processes CR and GR using the calculated shift voltages (S210). After the read process CR, the sense circuit SA transfers the data read in the read process CR to the latch circuit ADL. The sense circuit SA also transfers the data read in the read process CR to the latch circuit XDL. After the read process GR, the sense circuit SA transfers the data read in the read process GR to the latch circuit BDL. Then, the sense circuit SA transmits inverted data of the data read in the read process GR to the latch circuit XDL and performs an EXOR operation. As a result, the upper page data is stored in the latch circuit XDL. The non-volatile memory 10 outputs the upper page data stored in the latch circuit XDL to the memory controller 20. The shift amounts ΔCV and ΔGV obtained at this time may be transmitted to the corresponding parameter registers 120 in the logic control circuit 12 and stored therein.

In the manner described above, the first shift read is executed. Before S201, during the reading of the lower page, the memory controller 20 may issue a command instructing the execution of only a tracking read (without executing a calibrated read). In this case, an additional process in which the memory controller 20 issues a command instructing a shift read of the lower page is inserted between S203 and S204.

### 2.2.2.3 Command Sequence of First Shift Read

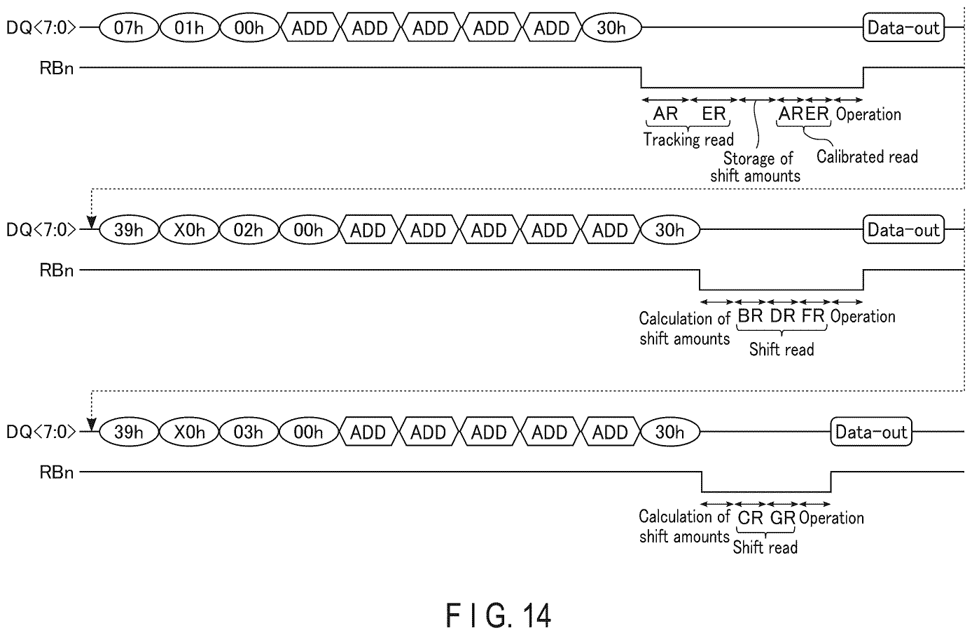

FIG. 14 is a command sequence diagram illustrating an example of the first shift read performed in the memory system according to the embodiment. FIG. 14 shows commands and data transmitted and received by the signal DQ<7:0>, together with waveform diagrams of ready/busy signals RBn. An example of a command sequence of the first shift read will be described with reference to FIG. 14. In the example shown in FIG. 14, the non-volatile memory 10 is configured by default to perform a calibrated read after a tracking read when it receives a command instructing the tracking read.

As shown in FIG. 14, the memory controller 20 first transmits a command “07h” to the non-volatile memory 10. The command “07h” is a command that designates a tracking read as a read process. The memory controller 20 then transmits a command “01h” and a command “00h.” The command “01h” is a prefix command that designates a lower page. The command “00h” indicates the execution of the read process. Then, the memory controller 20 transmits, for example, a 5-cycle address “ADD.” This address “ADD” is the address of the selected cell unit CU. The number of address cycles is arbitrary. Then, the memory controller 20 transmits a command “30h” to the non-volatile memory 10. The command “30h” is a command to execute the read process.

Upon receipt of the command “30h,” the sequencer 14 sets the ready/busy signal RBn to the “L” level. Then, the sequencer 14 executes a tracking read of the lower page, based on the commands “07h” and “01h,” and shift amounts ΔAV and ΔEV are estimated. Then, the shift amounts ΔAV and ΔEV obtained as a result of the tracking read are stored in the corresponding parameter registers 120. Thereafter, the sequencer 14 sequentially executes read processes AR and ER corresponding to the calibrated read, using shift voltages AV′ and EV′, and performs an EXOR operation. When the shift amounts ΔAV and ΔEV are stored in the corresponding parameter registers 120 and the lower page data is stored in the latch circuit XDL, the sequencer 14 sets the ready-busy signal RBn to the “H” level. The non-volatile memory 10 then outputs read data (Data-out) to the memory controller 20. At this time, the read data includes the lower page data.

Thereafter, the memory controller 20 successively transmits a command “39h” and a command “X0h” to the non-volatile memory 10. The command “39h” is a command that designates a shift read as the read process, and the command “X0h” is a command that designates the first shift read among the shift reads. The memory controller 20 then transmits a command “02h” and a command “00h.” The command “02h” is a prefix command that designates a middle page. Then, the memory controller 20 transmits, for example, a 5-cycle address “ADD.” This address “ADD” is the address of the selected cell unit CU. Then, the memory controller 20 transmits a command “30h” to the non-volatile memory 10.

Upon receipt of the command “30h,” the sequencer 14 sets the ready/busy signal RBn to the “L” level. Then, the sequencer 14 reads shift amounts ΔAV and ΔEV of the lower page from the corresponding parameter registers 120, based on the commands “39h,” “X0h” and “02h,” and calculates shift amounts ΔBV, ΔDV and ΔFV of the middle page, using the read shift amounts. Then, the sequencer 14 sequentially executes read processes BR, DR, and FR, using shift voltages BV′, DV′, and FV′ shifted by the calculated shift amounts ΔBV, ΔDV, and ΔFV, and performs an EXOR operation. When the middle page data is stored in the latch circuit XDL, the sequencer 14 sets the ready/busy signal RBn to the “H” level. Then, the non-volatile memory 10 outputs read data (Data-out) to the memory controller 20. At this time, the read data includes the middle page data.

Thereafter, the memory controller 20 successively transmits a command “39h,” a command “X0h,” a command “03h,” and a command “00h” to the non-volatile memory 10. The command “03h” is a prefix command that designates an upper page. Then, the memory controller 20 transmits, for example, a 5-cycle address “ADD.” This address “ADD” is the address of the selected cell unit CU. Then, the memory controller 20 transmits a command “30h” to the non-volatile memory 10.

Upon receipt of the command “30h,” the sequencer 14 sets the ready/busy signal RBn to the “L” level. Then, the sequencer 14 reads the shift amounts ΔAV and ΔEV of the lower page from the corresponding parameter registers 120, based on the commands “39h,” “X0h,” and “03h,” and uses the read shift amounts to calculate shift amounts ΔCV and ΔGV of the upper page. Thereafter, the sequencer 14 sequentially executes read processes CR and GR, using shift voltages CV′ and GV′ shifted by the calculated shift amounts ΔCV and ΔGV, and performs an EXOR operation. When the upper page data is stored in the latch circuit XDL, the sequencer 14 sets the ready-busy signal RBn to the “H” level. Then, the non-volatile memory 10 outputs read data (Data-out) to the memory controller 20. At this time, the read data includes the upper page data.

By transmitting the above commands to the non-volatile memory 10, the memory controller 20 executes the tracking read and the first shift read.

In connection with the command sequence shown in FIG. 14, a description was given of an example in which the tracking read and the first shift read are executed in succession; however, the tracking read and the first shift read do not necessarily have to be executed in succession. For example, the tracking read may be executed in advance to store the shift amounts ΔAV and ΔEV in the parameter registers 120, and after performing other operations, the first shift read using the shift amounts ΔAV and ΔEV may be executed. In addition, when the first shift reads of the same cell unit CU are executed consecutively within a short period of time, the tracking read may be omitted in the second read, and only the first shift read using the shift amounts ΔAV and ΔEV stored in the parameter registers 120 may be executed.

### 2.2.3 Second Shift Read

In the second shift read, one cell unit is selected as a sample from among the plurality of cell units CU provided in the same block BLK, and a tracking read is performed for the read voltages corresponding to the read processes of all pages stored in the cell unit. From the results of this tracking read, shift amounts corresponding to other cell units CU in the same block BLK are estimated, and a shift read is performed using shift voltages calculated based on the shift amounts. In the description below, the cell unit for which the tracking read is executed as a sample will be referred to as a sample cell unit CUsmp, and the read process, read voltage, shift voltage, and shift amount corresponding to the sample cell unit CUsmp are distinguished by appending the suffix “smp” to each term. In addition, the cell unit selected as the read target in the second shift read will be referred to as a selected cell unit CUsel, and the read process, read voltage, shift voltage, and shift amount corresponding to the selected cell unit CUsel are distinguished by appending the suffix “sel” to each term. The sample cell unit CUsmp and the selected cell unit CUsel are provided in the same block BLK.

### 2.2.3.1 Shift Amount Estimation

In the example described below, a tracking read of the read voltages AVsmp to GVsmp in the sample cell unit CUsmp is performed to estimate shift voltages AVsmp′ to GVsmp′. Then, shift voltages AVsel′ to GVsel′ in the selected cell unit CUsel are estimated from the results of the tracking read. For example, the shift amount ΔAVsel of the read voltage AVsel is estimated from the shift amount ΔAVsmp of the read voltage AVsmp. The shift amount ΔBVsel of the read voltage BVsel is estimated from the shift amount ΔBVsmp of the read voltage BVsmp. The shift amount ΔCVsel of the read voltage CVsel is estimated from the shift amount ΔCVsmp of the read voltage CVsmp. The shift amount ΔDVsel of the read voltage DVsel is estimated from the shift amount ΔDVsmp of the read voltage DVsmp. The shift amount ΔEVsel of the read voltage EVsel is estimated from the shift amount ΔEVsmp of the read voltage EVsmp. The shift amount ΔFVsel of the read voltage FVsel is estimated from the shift amount ΔFVsmp of the read voltage FVsmp. The shift amount ΔGVsel of the read voltage GVsel is estimated from the shift amount ΔGVsmp of the read voltage GVsmp. Then, shift voltages AVsel′ to GVsel′ shifted by the estimated shift amounts are calculated, and the data stored in the selected cell unit CUsel is read using the calculated shift voltages.

The shift amount Y of each read voltage in the selected cell unit CUsel is associated with the shift amount X of each read voltage in the sample cell unit CUsmp, for example, by the following Equation (2):

$$Y = X + c + e \qquad ( 2 )$$

It should be noted that the shift amount X is the difference between the initially set read voltage in the sample cell unit CUsmp and the voltage at the minimum point of the threshold voltage distribution function, and includes ΔAVsmp (=AVsmp′−AVsmp) to ΔGVsmp (=GVsmp′−GVsmp). The shift amount Y is the difference between the initially set read voltage in the selected cell unit CUsel and the voltage at the minimum point of the threshold voltage change, and includes ΔAVsel (=AVsel′−AVsel) to ΔGVsel (=GVsel′−GVsel). The coefficient “c” is a preset value for calculating the shift amount Y, based on the shift amount X. The coefficient “c” is set, for example, according to the position of the layer of the word line WL to which the sample cell unit CUsmp and the selected cell unit CUsel are coupled in the stacked interconnect structure of the memory cell array 17. The coefficient “e” represents an error term.

As can be seen from this, there is a correlation between the shift amount X and the shift amount Y, so that the shift amount of the selected cell unit CUsel can be estimated by detecting the shift amount of the sample cell unit CUsmp.

Equation (2) describes the case where the shift amounts X and Y are associated by a linear function with a slope of 1, but the association is not limited thereto. For example, the shift amounts X and Y may be associated by an arbitrary polynomial function.

### 2.2.3.2 Flow of Second Shift Read

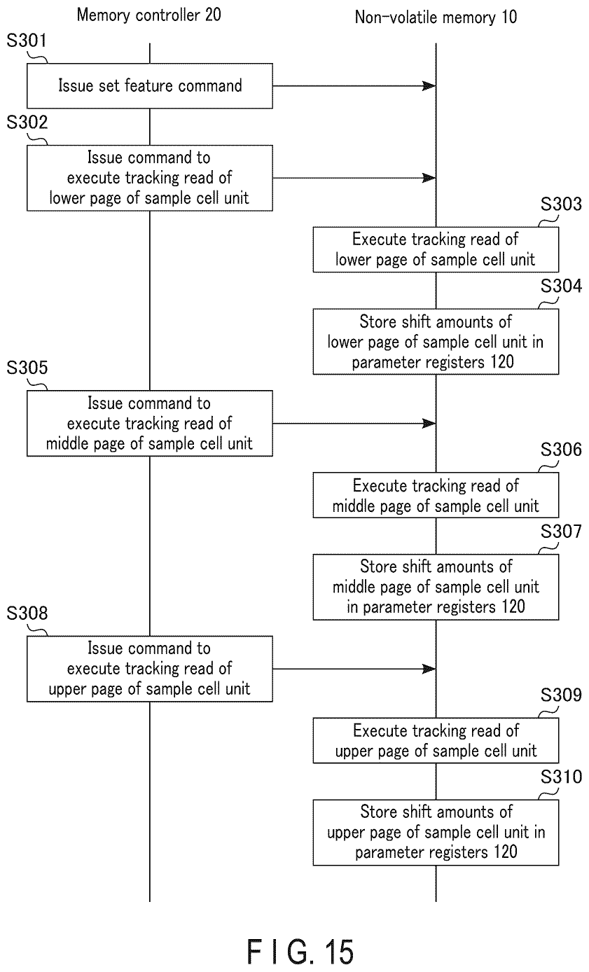

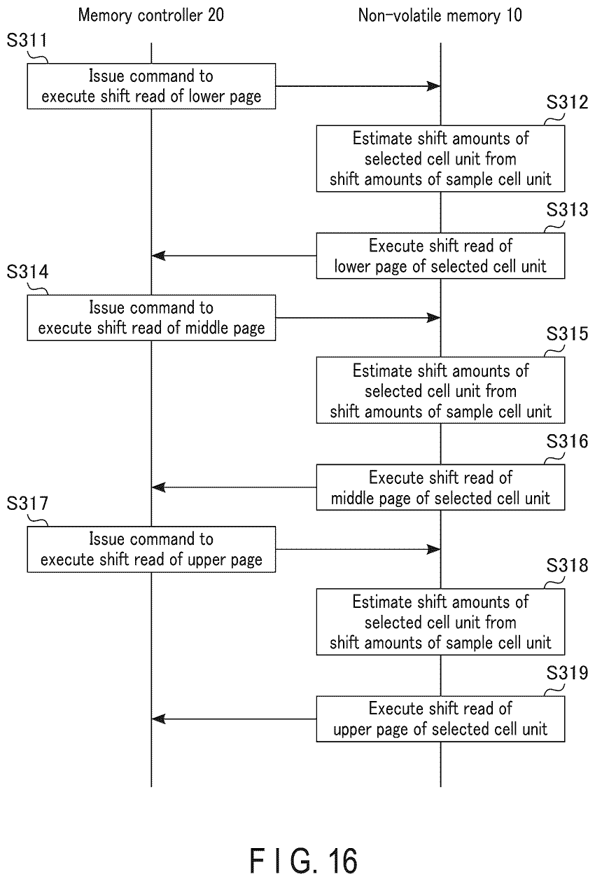

FIG. 15 is a sequence diagram illustrating an example of a process which the non-volatile memory and memory controller according to the embodiment perform when a tracking read corresponding to a second shift read is executed. FIG. 16 is a sequence diagram illustrating an example of a process which the non-volatile memory and memory controller according to the embodiment perform when the second shift read is executed. In the second shift read, a tracking read is first executed for each read voltage of the sample cell unit CUsmp, as shown in FIG. 15. Then, as shown in FIG. 16, a second shift read is executed for the selected cell unit CUsel. It should be noted that the tracking read and the second shift read do not necessarily have to be executed in succession. The second shift read of the selected cell unit CUsel may be executed at any time after the tracking read of the sample cell unit CUsmp in the same block BLK has been executed and before the tracking read of the sample cell unit CUsmp in another block BLK within the same plane PB is executed.

The flow of the tracking read corresponding to the second shift read will be described with reference to FIG. 15.

First, the memory controller 20 issues a set feature command to the non-volatile memory 10 (S301). The set feature command mentioned here refers to a command that instructs not to execute a calibrated read after the tracking read at each level.

The memory controller 20 then issues a command to the non-volatile memory 10 to execute a tracking read of the lower page of a sample cell unit CUsmp selected as a sample (S302). Upon receipt of the tracking read command of the lower page, the non-volatile memory 10 executes a tracking read of the lower page of the sample cell unit CUsmp (S303). As a result of the tracking read, shift voltages AVsmp′ and EVsmp′ that are the minimum points of the threshold voltage distribution function are estimated, and shift amounts ΔAVsmp and ΔEVsmp are calculated from the estimated shift voltages. Then, the non-volatile memory 10 stores the shift amounts ΔAVsmp and ΔEVsmp obtained as a result of the tracking read in the corresponding parameter registers 120 in the logic control circuit 12 (S304).

Next, the memory controller 20 issues a command to the non-volatile memory 10 to execute a tracking read of the middle page of the sample cell unit CUsmp (S305). Upon receipt of the tracking read command of the middle page, the non-volatile memory 10 executes a tracking read of the middle page of the sample cell unit CUsmp (S306). As a result of the tracking read, shift voltages BVsmp', DVsmp', and FVsmp′ which are the minimum points of the threshold voltage distribution function are estimated, and shift amounts ΔBVsmp, ΔDVsmp, and ΔFVsmp are calculated from the estimated shift voltages, respectively. Thereafter, the non-volatile memory 10 stores the shift amounts ΔBVsmp, ΔDVsmp, and ΔFVsmp obtained as a result of the tracking read in the corresponding parameter registers 120 in the logic control circuit 12 (S307).

Next, the memory controller 20 issues a command to the non-volatile memory 10 to execute a tracking read of the upper page of the sample cell unit CUsmp (S308). Upon receipt of the tracking read command of the upper page, the non-volatile memory 10 executes a tracking read of the upper page of the sample cell unit CUsmp (S309). As a result of the tracking read, shift voltages CVsmp′ and GVsmp′ corresponding to the minimum points of the threshold voltage distribution function are estimated, and shift amounts ΔCVsmp and ΔGVsmp are calculated from the estimated shift voltages, respectively. Thereafter, the non-volatile memory 10 stores the shift amounts ΔCVsmp and ΔGVsmp obtained as a result of the tracking read in the corresponding parameter registers 120 in the logic control circuit 12 (S310).

Next, the flow of the second shift read will be described with reference to FIG. 16.

First, the memory controller 20 issues a command to the non-volatile memory 10 to execute a second shift read of the lower page of the selected cell unit CUsel (S311). Upon receipt of the second shift read command of the lower page, the non-volatile memory 10 refers to the shift amounts ΔAVsmp and ΔEVsmp stored in the corresponding parameter registers 120 and estimates shift amounts ΔAVsel and ΔEVsel, using, for example, Equation (2) (S312).

Then, the non-volatile memory 10 calculates shift voltages AVsel′ and EVsel′ from the estimated shift amounts ΔAVsel and ΔEVsel, and sequentially executes read processes AR and ER using the calculated shift voltages (S313). The read processes AR and ER executed here and the subsequent operation processes are similar to the read processes AR and ER executed in the first shift read and the operation processes. The non-volatile memory 10 outputs the lower page data to the memory controller 20.

The memory controller 20 then issues a command to the non-volatile memory 10 to execute a second shift read of the middle page of the selected cell unit CUsel (S314). Upon receipt of the second shift read command of the middle page, the non-volatile memory 10 refers to the shift amounts ΔBVsmp, ΔDVsmp, and ΔFVsmp stored in the corresponding parameter registers 120 and estimates shift amounts ΔBVsel, ΔDVsel, and ΔFVsel, using, for example, Equation (2) (S315).

Then, the non-volatile memory 10 calculates shift voltages BVsel′, DVsel′, and FVsel′ from the estimated shift amounts ΔBVsel, ΔDVsel, and ΔFVsel, and sequentially executes the read processes BR, DR, and FR, using the calculates shift voltages (S316). The read processes BR, DR, and FR executed here and the subsequent operation processes are similar to the read processes BR, DR, and FR executed in the first shift read and the operation processes. The non-volatile memory 10 outputs the middle page data to the memory controller 20.

The memory controller 20 then issues a command to the non-volatile memory 10 to execute a second shift read of the upper page of the selected cell unit CUsel (S317). Upon receipt of the second shift read command of the upper page, the non-volatile memory 10 refers to the shift amounts ΔCVsmp and ΔGVsmp stored in the corresponding parameter registers 120, and estimates shift amounts ΔCVsel and ΔGVsel, for example, using Equation (2) (S318).

Thereafter, the non-volatile memory 10 calculates shift voltages CVsel′ and GVsel′ from the estimated shift amounts ΔCVsel and ΔGVsel, and sequentially executes read processes CR and GR using the calculated shift voltages (S319). The read processes CR and GR executed here and the subsequent operation processes are similar to the read processes CR and GR executed in the first shift read and the operation processes. The non-volatile memory 10 outputs the upper page data to the memory controller 20.

In this manner, the second shift read is executed. The second shift read is mainly used when consecutive read operations are performed on cell units CU within the same block. In a case where the read operation of a certain cell unit CU has been completed and another cell unit CU included in the same block BLK is selected for reading, the processes of S301 to S310 may be omitted, and the shift amounts ΔAVsmp to ΔGVsmp stored in the parameter register 120 may be reused to execute the processes of S311 to S319. In a case where a cell unit CU in another block BLK in the same plane PB is read, a sample cell unit CUsmp is selected from the block BLK and a tracking read is executed again.

It should be noted that, in the second shift read, the first shift read may be used to estimate the shift amount of the sample cell unit CUsmp. For example, a tracking read is executed on the lower page of the sample cell unit CUsmp, and shift amounts ΔAVsmp and ΔEVsmp are estimated and stored in the parameter registers 120. Thereafter, a first shift read is performed on the middle page and upper page of the sample cell unit CUsmp, and shift amounts ΔBVsmp, ΔCVsmp, ΔDVsmp, ΔFVsmp, and ΔGVsmp are estimated. The estimated shift amounts ΔBVsmp, ΔCVsmp, ΔDVsmp, ΔFVsmp, and ΔGVsmp are stored in the parameter registers 120 and used as reference values in the second shift read.

### 2.2.3.3 Command Sequence of Second Shift Read

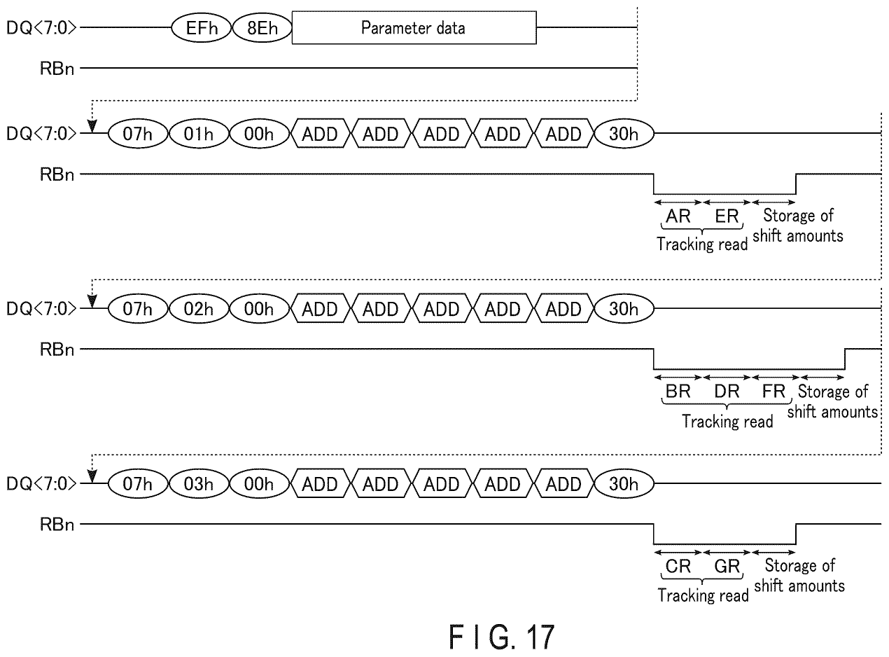

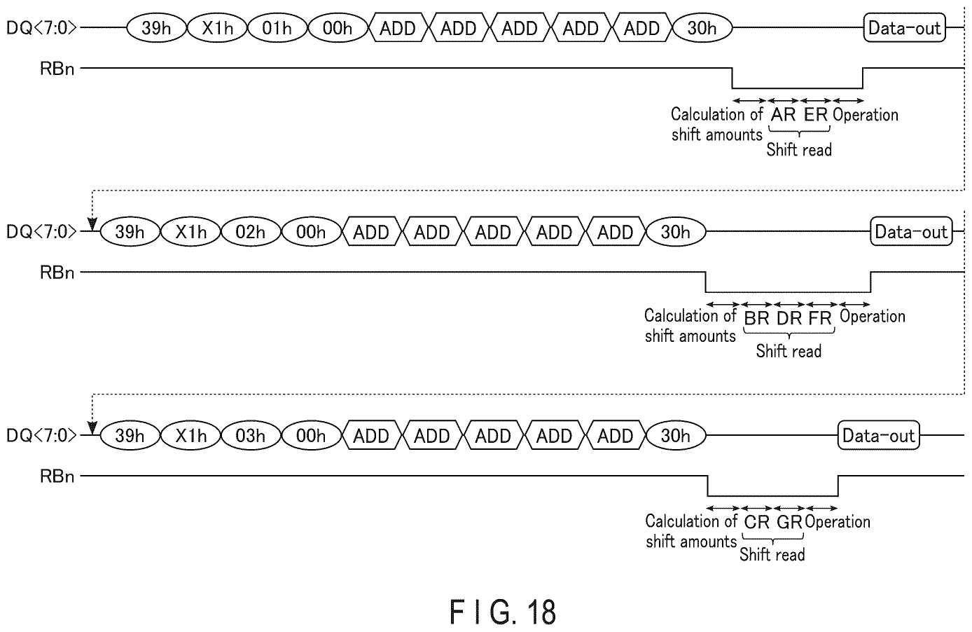

FIG. 17 is a command sequence diagram illustrating an example of a tracking read, which corresponds to the second shift read and is performed in the memory system according to the embodiment. FIG. 18 is a command sequence diagram showing an example of the second shift read performed in the memory system according to the embodiment. FIGS. 17 and 18 show commands and data transmitted and received by the signal DQ<7:0>, together with waveform diagrams of ready/busy signals RBn. An example of the command sequence of the second shift read will be described with reference to FIG. 17 and FIG. 18.

As shown in FIG. 17, the memory controller 20 first transmits a command “EFh” and a command “8Eh” to the non-volatile memory 10. The command “EFh” is a set feature command that indicates changes in various processing modes. The “8Eh” command is a feature address command that indicates which processing mode is to be changed. The memory controller 20 transmits parameter data in succession to the command “8Eh.” The parameter data is used to configure the system so that a calibrated read is not executed after a tracking read.

Then, the memory controller 20 transmits a command “07h” to the non-volatile memory 10. The command “07h” is a command that designates a tracking read as a read process. The memory controller 20 then transmits a command “01h” and a command “00h.” The command “01h” is a prefix command that designates a lower page. The command “00h” indicates the execution of a read process. Then, the memory controller 20 transmits, for example, a 5-cycle address “ADD.” This address “ADD” is the address of the sample cell unit CUsmp. The number of address cycles is arbitrary. Then, the memory controller 20 transmits a command “30h” to the non-volatile memory 10. The command “30h” is a command to execute a read process.

Upon receipt of the command “30h,” the sequencer 14 sets the ready/busy signal RBn to the “L” level. Then, the sequencer 14 executes a tracking read of the lower page of the sample unit CUsmp, based on the commands “07h” and “01h,” and shift amounts ΔAVsmp and ΔEVsmp are estimated. Thereafter, the shift amounts ΔAVsmp and ΔEVsmp obtained as a result of the tracking read are stored in the corresponding parameter registers 120. When the shift amounts ΔAVsmp and ΔEVsmp are stored in the corresponding parameter registers 120, the sequencer 14 sets the ready/busy signal RBn to the “H” level.

Next, the memory controller 20 successively transmits a command “07h,” a command “02h,” and a command “00h” to the non-volatile memory 10. The command “02h” is a prefix command that designates a middle page. Then, the memory controller 20 transmits, for example, a 5-cycle address “ADD.” This address “ADD” is the address of the sample cell unit CUsmp. Then, the memory controller 20 transmits a command “30h” to the non-volatile memory 10.

Upon receipt of the command “30h,” the sequencer 14 sets the ready/busy signal RBn to the “L” level. Then, based on the commands “07h” and “02h,” the sequencer 14 executes a tracking read of the middle page of the sample cell unit CUsmp, and shift amounts ΔBVsmp, ΔDVsmp, and ΔFVsmp are estimated. Then, the shift amounts ΔBVsmp, ΔDVsmp, and ΔFVsmp obtained as a result of the tracking read are stored in the corresponding parameter registers 120. When the shift amounts ΔBVsmp, ΔDVsmp, and ΔFVsmp are stored in the corresponding parameter registers 120, the sequencer 14 sets the ready/busy signal RBn to the “H” level.

Next, the memory controller 20 successively transmits commands “07h,” “03h,” and “00h” to the non-volatile memory 10. The command “03h” is a prefix command that designates an upper page. Then, the memory controller 20 transmits, for example, a 5-cycle address “ADD.” This address “ADD” is the address of the sample cell unit CUsmp. Then, the memory controller 20 transmits a command “30h” to the non-volatile memory 10.

Upon receipt of the command “30h,” the sequencer 14 sets the ready/busy signal RBn to the “L” level. Then, the sequencer 14 executes a tracking read of the upper page of the sample unit CUsmp, based on the commands “07h” and “03h,” and shift amounts ΔCVsmp and ΔGVsmp are estimated. Thereafter, the shift amounts ΔCVsmp and ΔGVsmp obtained as a result of the tracking read are stored in the corresponding parameter registers 120. When the shift amounts ΔCVsmp and ΔGVsmp are stored in the corresponding parameter registers 120, the sequencer 14 sets the ready/busy signal RBn to the “H” level.

Thereafter, as shown in FIG. 18, the memory controller 20 successively transmits a command “39h” and a command “X1h” to the non-volatile memory 10. The command “39h” is a command that designates a shift read as a read process, and the command “X1h” is a command that designates a second shift read among the shift reads. The memory controller 20 then transmits a command “01h” and a command “00h.” The command “01h” is a prefix command that designates a lower page, and the command “00h” indicates the execution of a read process. Next, the memory controller 20 transmits, for example, a 5-cycle address “ADD.” This address “ADD” is the address of the selected cell unit CUsel. The number of address cycles is arbitrary. Then, the memory controller 20 transmits the command “30h” to the non-volatile memory 10.

Upon receipt of the command “30h,” the sequencer 14 sets the ready/busy signal RBn to the “L” level. Then, based on the commands “39h,” “X1h” and “01h,” the sequencer 14 reads the shift amounts ΔAVsmp and ΔEVsmp of the lower page of the sample cell unit CUsmp from the corresponding parameter registers 120, and uses the read shift amounts to calculate shift amounts ΔAVsel and ΔEVsel of the lower page of the selected cell unit CUsel. Then, for the selected cell unit CUsel, the sequencer 14 sequentially executes the read processes AR and ER using the shift voltages AVsel′ and EVsel′, which are shifted by the calculated shift amounts ΔAVsel and ΔEVsel, and performs an EXOR operation. When the lower page data is stored in the latch circuit XDL, the sequencer 14 sets the ready/busy signal RBn to the “H” level. The non-volatile memory 10 then outputs read data (Data-out) to the memory controller 20. At this time, the read data includes the lower page data of the selected cell unit CUsel.

Next, the memory controller 20 transmits a command “39h,” a command “X1h,” a command “02h,” and a command “00h” to the non-volatile memory 10. The command “02h” is a prefix command that designates a middle page. Next, the memory controller 20 transmits, for example, a 5-cycle address “ADD.” This address “ADD” is the address of the selected cell unit CUsel. Then, the memory controller 20 transmits a command “30h” to the non-volatile memory 10.

Upon receipt of the command “30h,” the sequencer 14 sets the ready/busy signal RBn to the “L” level. Then, based on the commands “39h,” “X1h” and “02h,” the sequencer 14 reads the shift amounts ΔBVsmp, ΔDVsmp, and ΔFVsmp of the middle page of the sample cell unit CUsmp from the corresponding parameter registers 120, and uses the read shift amounts to calculate shift amounts ΔBVsel, ΔDVsel, and ΔFVsel of the middle page of the selected cell unit CUsel. Then, the sequencer 14 sequentially executes read processes BR, DR, and FR, and performs an EXOR operation, for the selected cell unit CUsel, using shift voltages BVsel′, DVsel′, and FVsel′ shifted by the calculated shift amounts ΔBVsel, ΔDVsel, and ΔFVsel. When the middle page data is stored in the latch circuit XDL, the sequencer 14 sets the ready/busy signal RBn to the “H” level. The non-volatile memory 10 then outputs read data (Data-out) to the memory controller 20. At this time, the read data includes the middle page data of the selected cell unit CUsel.

Next, the memory controller 20 transmits a command “39h,” a command “X1h,” a command “03h,” and a command “00h” to the non-volatile memory 10. The command “03h” is a prefix command that designates an upper page. Next, the memory controller 20 transmits, for example, a 5-cycle address “ADD.” This address “ADD” is the address of the selected cell unit CUsel. Then, the memory controller 20 transmits a command “30h” to the non-volatile memory 10.

Upon receipt of the command “30h,” the sequencer 14 sets the ready/busy signal RBn to the “L” level. Then, based on the commands “39h,” “X1h” and “03h,” the sequencer 14 reads the shift amounts ΔCVsmp and ΔGVsmp of the upper page of the sample cell unit CUsmp from the corresponding parameter registers 120, and uses the read shift amounts to calculate shift amounts ΔCVsel and ΔGVsel of the upper page of the selected cell unit CUsel. Then, for the selected cell unit CUsel, the sequencer 14 sequentially executes read processes CR and GR using shift voltages CVsel′ and GVsel′, which are shifted by the calculated shift amounts ΔCVsel and ΔGVsel, and performs an EXOR operation. When the upper page data is stored in the latch circuit XDL, the sequencer 14 sets the ready-busy signal RBn to the “H” level. The non-volatile memory 10 then outputs read data (Data-out) to the memory controller 20. At this time, the read data includes the upper page data of the selected cell unit CUsel.

By transmitting the above commands to the non-volatile memory 10, the memory controller 20 executes the tracking read and the second shift read.

### 2.2.3.4 Application to Asynchronous Independent Plane Read

The planes PB0 to PB3 of the non-volatile memory 10 can operate independently of each other. Therefore, data stored in a plurality of cell units CU included in different planes PB can be read in parallel. This process is referred to as an asynchronous independent plane read (AIPR). In the description below, reference will be made to the process of applying the second shift read to the asynchronous independent plane read.

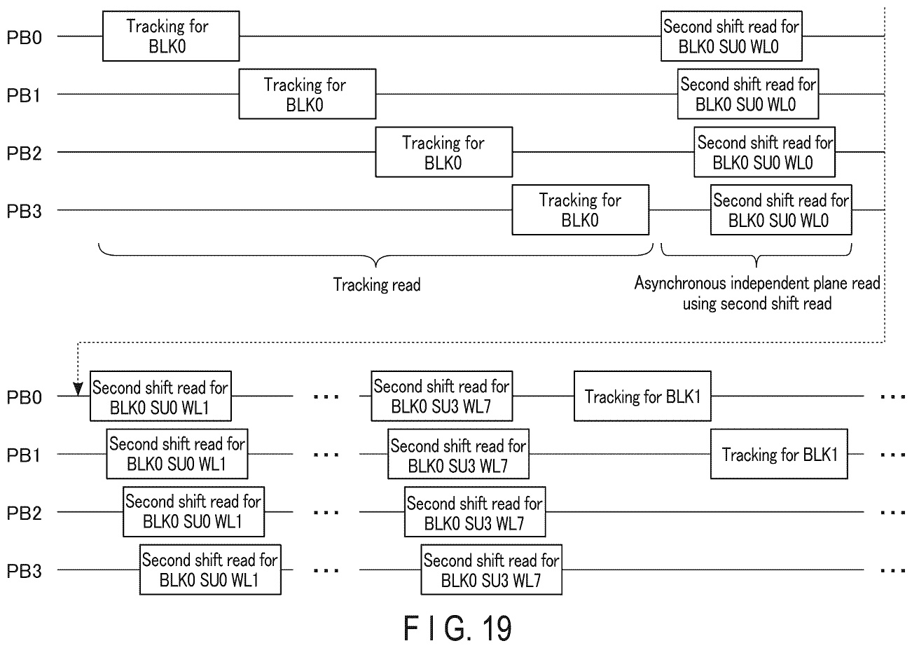

FIG. 19 is a sequence diagram illustrating an example of a read process flow for each plane, performed in the memory system according to the embodiment when a second shift read is applied to an asynchronous independent plane read. The flow of asynchronous independent plane read using the second shift read will be described with reference to FIG. 19.

First, the memory controller 20 selects one block BLK to be read from each plane PB. In the example shown in FIG. 19, the block BLK0 is selected from each of the planes PB0 to PB3. Next, the memory controller 20 selects a sample cell unit CUsmp from each selected block BLK, and executes a tracking read for each selected sample cell unit CUsmp. Since asynchronous independent plane read cannot be applied to tracking reads, a tracking read has to be executed for each plane PB. Then, the shift amounts of the sample cell units CUsmp in the block BLK0 of each plane PB are stored in the plurality of parameter registers 120. In the example shown in FIG. 19, tracking reads of the four blocks BLK0 selected from each plane PB are executed consecutively, but this is not intended to be limiting. For example, when the memory controller 20 and the plane PB including the block BLK are not performing any other process (such as a read process or a write process) and are in a ready state, a tracking read of the sample cell unit CUsmp in the block BLK may be executed individually. For example, the memory controller 20 may issue a command instructing a tracking read without receiving a request from the host 2, and cause the non-volatile memory 10 to execute the tracking read.

After the tracking read of the block BLK0 selected from each plane PB is completed, an asynchronous independent plane read is performed. In the asynchronous independent plane read, the memory controller 20 selects a cell unit CUsel to be read from the selected block BLK0 in each plane PB, and executes a second shift read. In the example shown in FIG. 19, the cell unit CU coupled to the word line WL0 included in the string unit SU0 in the BLK0 of each plane PB is selected, and the second shift read is executed. At this time, the shift amount of the sample cell unit CUsmp is referred to and the calculation for calculating the shift amount is executed in each plane PB. In other words, during the second shift read, new commands need not be exchanged between the memory controller 20 and the plane PB including the selected block BLK. Accordingly, the memory controller 20 can issue a second shift read command for a cell unit CU in another plane PB, even while a second shift read is being executed in a plane PB for which a second shift read command has already been issued. Therefore, the second shift read process can be executed in parallel in the plurality of planes PB0 to PB3. When the read of the selected cell unit CUsel is completed, the memory controller 20 issues a command to instruct the second shift read of another cell unit CU in the same block BLK (in the example shown in FIG. 19, the cell unit CU coupled to the word line WL1 included in the string unit SU0). By repeating this process, all cell units CU associated with the word lines WL0 to WL7 in the string units SU0 to SU3 within the block BLK0 selected from each plane PB are read.

Once the read of all cell units CU in the selected block BLK (e.g., BLK0) of each plane is completed, the memory controller 20 selects another block BLK from each of the planes PB0 to PB3 (in the example shown in FIG. 19, BLK1 in each plane PB). Then, a sample cell unit CUsmp is selected from the block BLK, and a tracking read is executed on the selected sample cell unit CUsmp. At this point, the shift amount of the sample cell unit CUsmp from the previously read block (e.g., BLK0), which is stored in the parameter registers 120 in each plane PB, may be replaced with the shift amount of the sample cell unit CUsmp from the newly selected block (e.g., BLK1) to be read next. After the tracking read is completed in the selected block BLK in each plane PB, the asynchronous independent plane reads are performed.

As described above, by repeatedly performing tracking reads and asynchronous independent plane reads using the second shift read for each block BLK in each plane PB, the data stored in all cell units CU included in all blocks BLK can be read.

In the example shown in FIG. 19, the second shift read is executed in parallel across the planes PB. However, the tracking read and the second shift read may also be executed in parallel in different planes PB. It should be noted that only one plane PB can execute the tracking read at a time. By executing the tracking read and the second shift read in parallel, the wait time during the tracking read can be effectively used for data reading.

### 3. Advantages

The memory system 3 according to the embodiment can shorten the read time of data stored in the non-volatile memory. This advantage will be described below.

For example, a memory device that has been left unused for a long period without read or write operations is likely to have experienced changes in the threshold voltage distributions of the memory cell transistors MT storing the data, due to factors such as data disturbance or data retention. If data is read from such a memory device, a normal read may increase the number of bit errors, which in turn increases the possibility that correct data cannot be read and may potentially reduce the reliability of the memory. Therefore, in a case where data is read from such a memory device, a shift voltage is estimated through a tracking read, and the read operation is executed using the estimated shift voltage.

However, a tracking read takes longer than a normal read or a shift read because it applies a plurality of voltages sequentially to search for the minimum point voltage in a read process of one level. For example, a tracking read for searching for shift voltages AV′ and EV′ of the lower page takes about 200 μs to 300 μs. This is significantly longer than the time required for a normal read or a shift read (approximately 50 μs). Therefore, if a tracking read is executed for each threshold voltage distribution level of each cell unit CU, the read process may require an enormous amount of time.

By performing the first shift read, the memory system 3 according to the embodiment can estimate a shift amount of another page from the result of the tracking read of one page of the selected cell unit CU. Therefore, the number of threshold voltage distribution levels for which a tracking read is performed is reduced, and the time required for reading data can be shortened.

In addition, by performing the second shift read, the memory system according to the embodiment can estimate a shift amount of another cell unit CU included in the same block BLK as the sample cell unit CUsmp, based on the result of the tracking read of the sample cell unit CUsmp. Therefore, the number of cell units CU that require a tracking read can be limited to one per block BLK, thereby reducing the number of tracking read operations. As a result, the time required for reading data can be shortened.

Furthermore, the memory system 3 according to the embodiment can perform read processes in parallel in each plane PB by combining the asynchronous independent plane read with the second shift read. In addition, the tracking read and the read process can be executed in parallel across a plurality of different planes PB. These can further shorten the time required for data reading.

The asynchronous independent plane read using the second shift read is advantageous for sequential data reading and can be used, for example, when migrating an operating system (OS) stored in the non-volatile memory 10. When OS data is migrated, it is necessary to read almost all of the data stored in each block BLK, which makes the read process highly time-consuming. However, by performing asynchronous independent plane reads using the second shift read during data migration, the read time can be shortened, and the data in each block BLK can be read sequentially and accurately, even data disturbance or retention has occurred.

### 4. Modifications

The memory system 3 according to the embodiment described above can be modified in various manners. The first and second modifications of the embodiment will be described below, focusing on the differences from the embodiment.

### 4.1 First Modification

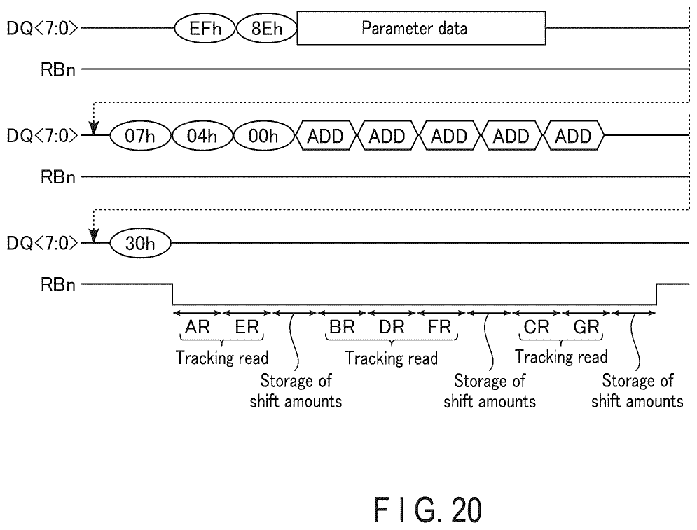

FIG. 20 is a command sequence diagram illustrating an example of a tracking read, which corresponds to a second shift read and is performed by a memory system according to the first modification of the embodiment. As shown in FIG. 20, the memory system 3 according to the first modification of the embodiment successively executes tracking reads on each page of the sample cell unit CUsmp.

Specifically, the memory controller 20 first transmits to the non-volatile memory 10 an “EFh” command, an “8Eh” command, and parameter data to change the setting so that calibrated read is not executed.

Next, the memory controller 20 transmits to the non-volatile memory 10 a command “07h,” and subsequently transmits a command “04h” and a command “00h.” The command “04h” is a prefix command that designates that tracking reads of all pages are to be executed in succession. Next, the memory controller 20 transmits, for example, a 5-cycle address “ADD.” This address “ADD” is the address of the sample cell unit CUsmp. The number of address cycles is arbitrary. Then, the memory controller 20 transmits a command “30h” to the non-volatile memory 10.

Upon receipt of the command “30h,” the sequencer 14 sets the ready/busy signal RBn to the “L” level. Then, the sequencer 14 first executes a tracking read of the lower page for the sample unit CUsmp, based on the commands “07h” and “04h,” and shift amounts ΔAVsmp and ΔEVsmp are estimated. Thereafter, the shift amounts ΔAVsmp and ΔEVsmp obtained as a result of the tracking read are stored in the corresponding parameter registers 120.

Once the shift amounts ΔAVsmp and ΔEVsmp are stored in the corresponding parameter registers 120, a tracking read of the middle page is executed for the sample cell unit CUsmp, and shift amounts ΔBVsmp, ΔDVsmp, and ΔFVsmp are estimated. Then, the shift amounts ΔBVsmp, ΔDVsmp, and ΔFVsmp obtained as a result of the tracking read are stored in the corresponding parameter registers 120.

Once the shift amounts ΔBVsmp, ΔDVsmp, and ΔFVsmp are stored in the corresponding parameter registers 120, a tracking read of the upper page is executed for the sample cell unit CUsmp, and shift amounts ΔCVsmp and ΔGVsmp are estimated. Thereafter, the shift amounts ΔCVsmp and ΔGVsmp obtained as a result of the tracking read are stored in the corresponding parameter registers 120. When the shift amounts ΔCVsmp and ΔGVsmp are stored in the corresponding parameter registers 120, the sequencer 14 sets the ready/busy signal RBn to the “H” level. Thereafter, the second shift read is executed in the same manner as in the embodiment.

In the memory system 3 according to the first modification of the embodiment, the memory controller 20 does not have to issue a command to instruct a tracking read for each page. Thus, the exchange of commands between the memory controller 20 and the non-volatile memory 10 can be omitted, and the command wait time can be shortened. Therefore, the time required for reading data can be shortened.

### 4.2 Second Modification

In the second modification of the embodiment, the memory system 3 can estimate a shift amount of a selected cell unit CUsel in a certain block BLK, based on the shift amount of a sample cell unit CUsmp in another block BLK within the same plane PB. The shift read using this shift amount estimation method is referred to as a third shift read. The process of the third shift read will be described below.

In a case where a plurality of cell units CU in different blocks BLKs within the same plane PB perform write, read, or erase operations approximately at the same time, the resulting variations in threshold voltage distribution, which are caused by data disturbance and data retention, can be considered similar across those cell units. Therefore, the shift amounts of the cell units CU provided in each block BLK can also be considered to be correlated, and can be used as a reference at the time of shift amount estimation. In the description below, reference will be made to the case where the sample cell unit CUsmp in block BLK0 is used to estimate a shift amount of a selected cell unit CUsel in block BLK1.

In a case where the fluctuations in the threshold voltage distributions of blocks BLK0 and BLK1 are considered to be similar, the tracking read of the sample cell unit CUsmp of block BLK1 is not executed. The memory controller 20 uses, for example, a set feature command and instructs the non-volatile memory 10 to estimate a shift amount of the selected cell unit CUsel of block BLK1 from the shift amount of the sample cell unit CUsmp of block BLK0 during the shift read. Then, the third shift read is executed. The shift amount of the selected cell unit CUsel in the third shift read is estimated using Equation (2), as in the estimation method of the shift amount of the selected cell unit CUsel in the second shift read.

The memory system according to the second modification of the embodiment executes the third shift read and shares the results of the tracking read referenced across blocks BLK, thereby reducing the total number of tracking reads required in the overall read operation. Therefore, the time required for reading data can be shortened.

### 5. Others

The embodiment described above is a case of executing the TLC mode where one memory cell transistor MT can store three bits of data, but this is not intended to be limiting. For example, the first shift read and the second shift read in the embodiment may be applied in a case where one memory cell transistor MT can store equal to or more than four bits of data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A memory device comprising:
a first memory cell array including a first memory cell coupled to a first word line and configured to memorize first data, and a second memory cell coupled to a second word line and configured to memorize second data;
a register; and
a sequencer,
wherein the first data includes a first bit,
the second data includes a second bit,
upon receipt of a first command, the sequencer executes a first process including:
applying a plurality of different voltages within a first range to the first word line to read the first bit from the first memory cell a plurality of times;
specifying a first voltage within the first range based on results of reading the first bit a plurality of times; and
storing a first parameter that specifies the first voltage in the register, and
upon receipt of a second command, the sequencer executes a second process including:
obtaining the first parameter from the register;
estimating a second voltage based on the first parameter; and
reading the second bit from the second memory cell using the second voltage.

2. The memory device according to claim 1, wherein the first parameter is a parameter indicating a difference between a third voltage within the first range and the first voltage.

3. The memory device according to claim 2, wherein the second voltage has a value obtained by adding a first variation estimated based on the first parameter to a value of a fourth voltage.

4. The memory device according to claim 3, wherein the third voltage and the fourth voltage are voltages having substantially equal magnitudes.

5. The memory device according to claim 4, wherein
the first memory cell array includes a plurality of blocks including a first block,
each of the plurality of blocks is an erase unit of a plurality of memory cells included in the first memory cell array, and
the first memory cell and the second memory cell are included in the first block.

6. The memory device according to claim 1, wherein the sequencer executes the first process and the second process in succession upon receipt of a third command.

7. The memory device according to claim 3, wherein
the first word line and the second word line are part of an identical word line,
the first memory cell and the second memory cell are portions of an identical memory cell,
the first data and the second data are portions of identical data,
the first bit and the second bit are different bits, and
the third voltage and the fourth voltage are voltages having different magnitudes.

8. The memory device according to claim 7, wherein the second process further includes:
causing the first variation estimated based on the first parameter to be stored in the register as a second parameter.

9. The memory device according to claim 8, wherein
the first memory cell array further includes a third memory cell coupled to a third word line and configured to memorize third data,
the third data includes a third bit and a fourth bit that are different from each other, and
upon receipt of a fourth command, the sequencer executes a third process including:
obtaining the first parameter and the second parameter from the register;
estimating a fifth voltage based on the first parameter;
estimating a sixth voltage based on the second parameter;
reading the third bit from the third memory cell using the fifth voltage; and
reading the fourth bit from the third memory cell using the sixth voltage.

10. The memory device according to claim 9, wherein
the fifth voltage has a value obtained by adding a second variation estimated based on the first parameter to a value of a seventh voltage, and
the sixth voltage has a value obtained by adding a third variation estimated based on the second parameter to a value of an eighth voltage.

11. The memory device according to claim 10, wherein
the third voltage and the seventh voltage are voltages having substantially equal magnitudes, and
the fourth voltage and the eighth voltage are voltages having substantially equal magnitudes.

12. The memory device according to claim 1, further comprising:
a second memory cell array that operates independently of the first memory cell array and that includes a fourth memory cell coupled to a fourth word line and configured to memorize fourth data,
wherein the fourth data includes a fifth bit,
upon receipt of a fifth command, the sequencer executes a fourth process including:
applying a plurality of different voltages within a second range to the fourth word line to read the fifth bit from the fourth memory cell a plurality of times;
specifying a ninth voltage within the second range based on results of reading the fifth bit a plurality of times; and
storing a third parameter specifying the ninth voltage in the register, and
the fourth process is executed in parallel with the second process.

13. The memory device according to claim 12, wherein
the second memory cell array further includes a fifth memory cell coupled to a fifth word line and configured to memorize fifth data,
the fifth data includes a sixth bit,
upon receipt of a sixth command, the sequencer executes a fifth process including:
obtaining the third parameter from the register;
estimating a tenth voltage based on the third parameter; and
applying the tenth voltage to the fifth word line to read the sixth bit from the fifth memory cell, and
the fifth process is executed in parallel with the first process and the second process.

14. A memory device comprising:
a first memory cell array including: a first cell unit coupled to a first word line and including a plurality of memory cells each configured to memorize first data; and a second cell unit coupled to a second word line and including a plurality of memory cells each configured to memorize second data;
a register; and
a sequencer,
wherein the first word line is associated with a first page,
the second word line is associated with a second page,
upon receipt of a first command, the sequencer executes a first process including:
applying a plurality of different voltages within a first range and a plurality of different voltages within a second range to the first word line to read the first page from the first cell unit a plurality of times;
specifying a first voltage within the first range and a second voltage within the second range based on results of reading the first page a plurality times; and
causing a first parameter that specifies the first voltage and a second parameter that specifies the second voltage to be stored in the register, and
upon receipt of a second command, the sequencer executes a second process including:
obtaining the first parameter and the second parameter from the register;
estimating a third voltage and a fourth voltage based on the first parameter or the second parameter; and
applying the third voltage and the fourth voltage to the second word line to read the second page from the second cell unit.

15. The memory device according to claim 14, wherein
the first parameter is a parameter indicating a difference between a fifth voltage within the first range and the first voltage, and
the second parameter is a parameter indicating a difference between a sixth voltage within the second range and the second voltage.

16. The memory device according to claim 15, wherein
the third voltage has a value obtained by adding a first variation estimated based on the first parameter or the second parameter to a value of a seventh voltage, and
the fourth voltage has a value obtained by adding a second variation estimated based on the first parameter or the second parameter to a value of an eighth voltage.

17. The memory device according to claim 16, wherein
the first word line and the second word line are portions of an identical word line, and
the first page and the second page are different pages.

18. The memory device according to claim 17, wherein
the first variation is estimated based on the first parameter in a case where a difference between the seventh voltage and the third voltage is smaller than, or equal to, a difference between the seventh voltage and the fourth voltage, and is estimated based on the second parameter in a case where the difference between the seventh voltage and the fourth voltage is smaller than the difference between the seventh voltage and the third voltage, and
the second variation is estimated based on the first parameter in a case where a difference between the eighth voltage and the third voltage is smaller than, or equal to, a difference between the eighth voltage and the fourth voltage, and is estimated based on the second parameter in a case where the difference between the eighth voltage and the fourth voltage is smaller than the difference between the eighth voltage and the third voltage.

19. A memory system comprising:
a memory device as recited in claim 1, and
a controller configured to issue the first command and the second command.

20. A memory system comprising:
a memory device as recited in claim 14, and
a controller configured to issue the first command and the second command.
